(19) United States
(12) Patent Application Publication
(10) Pub. No.: US 2023/0051884 A1
(43) Pub. Date: Feb. 16, 2023

(54) PHONONIC MATERIAL AND METHOD FOR PRODUCING SAME

(71) Applicant: Nobuyuki Zen, Ibaraki (JP)

(72) Inventor: Nobuyuki Zen, Ibaraki (JP)

(21) Appl. No.: 17/789,071

(22) PCT Filed: Dec. 23, 2020
(86) PCT No.: PCT/JP2020/048219

§ 371 Date: Jun. 24, 2022

(30) Foreign Application Priority Data
Dec. 28, 2019 (JP) 2019-239998

(51) Int. Cl. H01L 39/08; H01L 39/24

(52) U.S. Cl. CPC H01L 39/08; H01L 39/24

(57) ABSTRACT

[Problem] To provide a phononic material that exhibits a voltage-current characteristic to make current flow even when there is no potential gradient, and a method for producing the same. [Solution] A phononic material 1 has a periodic structure body 2′ in which structures 3 are periodically and regularly disposed in a constituent 2, and the periodic structure body 2′ exhibits a voltage-current characteristic to make current flow even when a potential gradient is 0 V. A method for producing the phononic material 1 has such an outline as to carry out a heat treatment to cool and warm the periodic structure body after applying a current with a magnitude to make an electrical resistance characteristic disappear to the periodic structure body 2′ having the electrical resistance characteristic that exhibits an electrical resistance value of 0Ω or less.

### TECHNICAL FIELD

The present invention relates to a phononic material that generates an electric current and a method for producing the same.

### BACKGROUND ART

Research on phonon engineering is underway to manipulate phonons propagating in a constituent artificially by periodically and regularly disposing arbitrary structures in the constituent.

For example, the present inventor succeeded in lowering the thermal conductivity of an insulator by about one order by applying phonon engineering to the insulator (see Non-Patent Document 1).

Further, there is a suggestion to try to improve the sensitivity of an infrared sensor by applying phonon engineering to beams, each composed of an insulator or a semiconductor and connected to an infrared receiver, to lower the thermal conductivity of the beam (see Patent Document 1).

In either case, the propagation of heat in the constituent is described by the propagation of phonons (lattice vibration). In general, although a phonon dispersion relation is defined by the type of constituent and the thermal conductivity is defined by an inherent phonon dispersion relation of the constituent, the inherent thermal conductivity of the insulator can be lowered by applying phonon engineering to the insulator to manipulate the phonon dispersion relation artificially.

Thus, attention is focused on phonon engineering to control the thermal conductivity artificially in the future, but further progress is required for technology related to superconductivity.

For example, research is being conducted to try to improve superconducting transition temperature using the structural change of a cage-shaped structure body, but the phonon dispersion relation is not affected because a structure having about an atomic-scale size (the order of picometers to the order of a few nanometers) is targeted as the cage-shaped structure.

In addition, it is found that the superconducting transition temperature of the cage-shaped structure is not improved, or rather that the inherent superconducting properties of the constituent of the cage-shaped structure body are impaired (see Non-Patent Documents 2 and 3).

In the meantime, the present inventor reports the transition of a phonon-engineered metal plate to an insulator by repeating the heat treatment of cooling and warming of the metal plate (phononic material) (see Non-Patent Document 4).

This indicates such a phenomenon that, when a periodic structure body in which structures are periodically and regularly disposed in a constituent is cooled, the material order of the constituent before cooling changes to form a new material order, and that this new material order is maintained after warming to give new physical properties that the constituent does not have by nature. Metals and semiconductors are different from insulators in that charged carriers such as electrons and holes exist in the constituent. Since this phenomenon is not confirmed even when a constituent to which the phonon engineering is not applied is cooled itself, the phenomenon is understood to be a phenomenon that occurs only in the constituent that constructs the periodic structure body, which is based on the interaction of phonons (lattice vibration) in the constituent that constructs the periodic structure body with carriers in the constituent when cooling and warming.

This means that the material order that the constituent cannot have by nature can be exhibited artificially through phonon control based on artificial settings of the structures disposed in the periodic structure body.

The most basic and important property of a superconductor is zero resistance. In other words, there is no electric field inside the superconductor even though the current is flowing inside the superconductor. The current flowing inside the superconductor at the time is called a superconducting current or a permanent current, but the permanent current does not flow out of the superconductor because there is no electric field inside the superconductor (see Non-Patent Document 5, pp. 25 and 26).

On the other hand, when two types of solids different in electron state, for example, a p-type semiconductor and an n-type semiconductor are brought into contact with each other, holes diffuse from the p-type semiconductor toward the n-type semiconductor and electrons diffuse from the n-type semiconductor toward the p-type semiconductor (carrier diffusion), respectively, at the contact interface to form a built-in electric field at the contact interface. At the time, there are no holes and electrons in the vicinity of the contact interface, and a pn junction having a layer called a depletion layer is formed.

Although holes and electrons are produced in the vicinity of the depletion layer when the pn junction is irradiated with light, the holes and the electrons are pushed out to the p-type semiconductor side and the n-type semiconductor side, respectively, by the built-in electric field. When the pn junction is connected to an external electrical circuit, the holes and the electrons thus pushed out can flow into the external electrical circuit as current, and the pn junction can be used as a solar cell.

However, the pn junction cannot apply current to the external electrical circuit without light irradiation. This is because carriers such as electrons and holes cannot exist inside the depletion layer unless there is a mechanism to generate the carriers by light irradiation.

In the meantime, when the superconductor is in contact with a solid different in electron state from the superconductor, a quantum mechanical tunneling phenomenon called Andreev reflection is observed at the interface. In the superconductor, there is a Cooper pair composed of two electrons condensed to Fermi level, but a gap corresponding to superconducting condensation energy A (superconducting gap) is open up and down of the Fermi level.

Even if electrons try to tunnel from the solid side to the superconductor side, the electrons cannot occupy the energy level on the superconductor side because there is no energy level as a destination of tunneled electrons due to the superconducting gap. Instead, the electrons are reflected as holes from the superconductor side to the solid side vice versa. This is the Andreev reflection. At the time, since electrons and holes with charged polarities opposite to each other go in the opposite directions, respectively, current flows into a junction composed of the superconductor and the solid (see Non-Patent Document 6, Section 11.5.1).

However, the Andreev reflection cannot be observed unless voltage is applied to both ends of the junction composed of the superconductor and the solid. Since the depletion layer as appearing in the pn junction does not exist at the junction interface of these, and hence there is no built-in electric field capable of pushing out carriers, carriers cannot perform acceleration motion from the solid side toward the superconductor side unless voltage is applied from outside to both ends of the junction.

A junction in which one side of the junction is the superconductor and the depletion layer is formed at the interface of the junction, that is, a junction structure having the built-in electric field cannot be produced with current microfabrication technology. As typical methods for producing the pn junction, there are diffusion bonding, alloy diffusion, and ion implantation method. However, all methods require impurities and to go through a high-energy production process such as high-temperature melting or high-voltage acceleration, and these become factors that impair properties as the superconductor that the junction has. The band gap of semiconductors used for the pn junction is energy on the order of a few eV, while the superconducting gap of a general superconductor is on the order of a few meV. The fact that the energy scales of these gaps are different by three orders of magnitude is the essential reason for making it difficult to produce the junction of the semiconductor and the superconductor.

As techniques related to the junction of the semiconductor and the superconductor, some suggestions have been made (see Patent Documents 2 and 3).

However, in both suggestions, a third different solid is inserted between the semiconductor and the superconductor. This is because respective properties as the superconductor and the semiconductor in the junction are impaired without the third solid. On the other hand, the depletion layer is not formed at the interface between the semiconductor and the superconductor as long as there is the third solid.

Therefore, there is no report that the junction of the semiconductor and the superconductor having the built-in electric field was realized, and consequently, there is no report example that a material capable of applying current without applying external voltage was realized.

### PRIOR ART DOCUMENTS

### Patent Document

Patent Document 1: Japanese Patent Application Publication No. 2017-223644
Patent Document 2: Japanese Patent Application Publication No. 2002-050802
Patent Document 3: Japanese Patent Application Publication No. 2012-038984

### Non-Patent Documents

Non-Patent Document 1: N. Zen et al., Nature Commun. 53435 (2014)
Non-Patent Document 2: J. Tang et al., Phys. Rev. Lett. 105, 176402 (2010)
Non-Patent Document 3: R. Ang et al., Nature Commun. 6:6091 (2015)
Non-Patent Document 4: N. Zen, AIP Adv. 9, 095023 (2019)
Non-Patent Document 5: Sadao Nakajima, Introduction to Superconductivity, Baifukan Co., Ltd. (1971)
Non-Patent Document 6: Michael Tinkham, Introduction to Superconductivity, (Vol. II), 2nd ed., Yoshioka Shoten Co., Ltd. (2006)
Non-Patent Document 7: J. Bardeen et al., Phys. Rev. 106, 162 (1957)

### SUMMARY OF THE INVENTION

### Problems to be Solved by the Invention

The present invention is to solve the various conventional problems and achieve the following object, that is, an object to provide a phononic material that exhibits a voltage-current characteristic to make current flow even when there is no potential gradient, and a method for producing the same.

A mechanism for the transition of a metal to a superconductor is described by BCS theory in which inter-electron interaction mediated by a phonon is written (see Non-Patent Document 7).

Although the present inventor aimed to develop properties as a superconductor artificially by controlling phonons in the phononic material based on the BCS theory, it resulted in the transition of the metal plate to the insulator as described above (see Non-Patent Document 4).

An Anderson localization phenomenon is observed in the insulator, and this suggests that carriers receive a spatial disturbance and cannot move.

Although the phenomenon in which the transition of the metal plate to the insulator is made is an unusual phenomenon in itself, the present inventor hypothesized that a special carrier movement characteristic can be developed in the interaction with phonons by performing the heat treatment by cooling and warming without giving any spatial disturbance to the carriers in the constituent, and after a further examination, the present inventor gained such a finding that the periodic structure body having zero resistance can be obtained.

Then, the present inventor applied current while gradually increasing the applied current value to find out a critical current value as a property (zero resistance) as the superconductor that this periodic structure body has. Further, the present inventor measured the electrical characteristics of the periodic structure body while changing the magnitude of the applied current in a range of negative to positive values to confirm that the periodic structure body after the application of current lost the properties as the superconductor.

As a result, zero resistance could not be confirmed from the periodic structure body after the application of a current of the critical current value or higher, and hence it could be confirmed that the properties as the superconductor were lost. On the other hand, such a strange phenomenon that properties as an insulator were confirmed with negative current values but properties as a metal appeared with small positive current values though the properties as the insulator appeared when the value increased.

For this phenomenon, the present inventor hypothesized that holes were formed (injected) in the periodic structure body through the application of current of the critical current value or more, and these holes behaved metallically when the amount of current is small in a positive current region and behaved as an insulator as the amount of current increased, i.e., that properties as a semiconductor having both side of a conductor and an insulator could be developed in the periodic structure body. Further, the present inventor hypothesized that, when the heat treatment of cooling and warming was performed again on the periodic structure body in this state to give the properties as the superconductor to the periodic structure body, the periodic structure body having both the properties as the semiconductor and the properties as the superconductor could be obtained.

If this hypothesis is right, such a property as the junction of the semiconductor and the superconductor that cannot be produced with conventional technology, that is, such a property as to make current flow without applying external voltage can also be expected.

The present inventor repeated tests to prove such a hypothesis, and finally gained a finding about a phononic material having the periodic structure body that exhibits a voltage-current characteristic to make current flow when the potential gradient is 0 V, and production conditions for the same.

### Means for Solving the Problems

The present invention is based on the finding, and means for solving the problems are as follows, namely:

<1> A phononic material including a periodic structure body in which structures are periodically and regularly disposed in a constituent containing elements having d orbital, wherein the periodic structure body exhibits a voltage-current characteristic to apply current when a potential gradient is 0 V.

<2> The phononic material described in <1>, wherein the periodic structure body can supply current to an external electrical circuit when the potential gradient is 0 V.

<3> The phononic material described in <1> or <2>, wherein the periodic structure body exhibits a voltage-current characteristic to apply current when a potential gradient is given.

<4> The phononic material described in any one of <1> to <3>, wherein the periodic structure body can supply current to an external electrical circuit when a potential gradient is given.

<5> The phononic material described in any one of <1> to <4>, wherein the constituent contains a transition metal element.

<6> The phononic material described in any one of <1> to <5>, wherein the periodic structure body is formed in a layer, and the structures are through holes.

<7> The phononic material described in <6>, wherein an opening diameter of each through hole is 1 nm to 10 mm.

<8> The phononic material described in <6> or <7>, wherein an interval between adjacent two through holes is 1 nm to 0.1 mm.

<9> The phononic material described in any one of <6> to <8>, wherein a thickness of the periodic structure body formed in the layer is 0.1 nm to 0.01 mm.

<10> A method for producing the phononic material described in any one of <1> to <9>, including: a pretreatment process to obtain a first precursor as the periodic structure body that does not develop a bifurcation phenomenon by carrying out a heat treatment to warm the periodic structure body up to a temperature exceeding a bifurcation temperature after cooling the periodic structure body up to a temperature lower than the bifurcation temperature in a state of applying a unidirectional current to the periodic structure body until the bifurcation phenomenon disappears, where the bifurcation phenomenon is a phenomenon in which, when a cooling resistance temperature characteristic of the periodic structure body in a cooling process of continuous heat cycles to raise temperature after cooling the periodic structure body is compared with a warming resistance temperature characteristic of the periodic structure body in a warming process, the warming resistance temperature characteristic bifurcates from the cooling resistance temperature characteristic to exhibit a high electrical resistance value at a common temperature, and the bifurcation temperature is a temperature at which the cooling resistance temperature characteristic and the warming resistance temperature characteristic bifurcate each other in the bifurcation phenomenon; a first cooling-warming process to obtain a second precursor as the periodic structure body having an electrical resistance characteristic exhibiting an electrical resistance value of 0Ω or less in a temperature range exceeding the bifurcation temperature by carrying out a heat treatment to warm the first precursor up to a temperature exceeding the bifurcation temperature after cooling the first precursor up to a temperature lower than the bifurcation temperature until the warmed first precursor exhibits the electrical resistance value of 0Ω or less; a current application process to obtain a third precursor as the periodic structure body that does not exhibit the electrical resistance characteristic by applying current with a magnitude of a critical current value or more to the second precursor in the same direction as the unidirectional current or a direction opposite thereto to lose the electrical resistance characteristic; and a second cooling-warming process to carry out a heat treatment to warm the third precursor up to a temperature exceeding the bifurcation temperature after cooling the third precursor up to a temperature lower than the bifurcation temperature until the third precursor exhibits a voltage-current characteristic to make current flow when a potential gradient is 0 V.

### Advantageous Effect of the Invention

According to the present invention, the various problems in the conventional technology can be solved, and a phononic material exhibiting a voltage-current characteristic to make current flow even when there is no potential gradient and a method for producing the same can be provided.

### BRIEF DESCRIPTION OF THE DRAWINGS

FIG. 1(a) is an explanatory drawing illustrating the top surface of a phononic material according to one embodiment of the present invention.

FIG. 1(b) is an explanatory drawing illustrating an A-A′ line section in FIG. 1(a).

FIG. 2(a) is a diagram (1) illustrating a modification of structures. FIG. 2(b) is a diagram (2) illustrating another modification of the structures.

FIG. 2(c) is a diagram (3) illustrating still another modification of the structures.

FIG. 2(d) is a diagram (4) illustrating yet another modification of the structures.

FIG. 3(a) is an explanatory drawing illustrating a configuration example of a one-dimensional phononic material.

FIG. 3(b) is an explanatory drawing (1) illustrating a configuration example of a three-dimensional phononic material.

FIG. 3(c) is an explanatory drawing (2) illustrating a configuration example of the three-dimensional phononic material.

FIG. 4 is an explanatory drawing illustrating the state of a niobium layer as viewed from the top.

FIG. 5 is an explanatory drawing illustrating each of rectangular block regions when the niobium layer is viewed from above.

FIG. 6(a) is a graph for describing the status of carrying out a pretreatment process on a phononic material according to Example 1 and the transition status of electrical resistance values.

FIG. 6(b) is a partially enlarged graph in which a range of 20 K to 60 K in FIG. 6(a) is enlarged.

FIG. 6(c) is a partially enlarged graph in the first cycle.

FIG. 6(d) is a partially enlarged graph in the sixth cycle.

FIG. 6(e) is a graph (1) illustrating the status of carrying out a first cooling-warming process on the phononic material according to Example 1 and the transition status of electrical resistance values.

FIG. 6(f) is a graph (2) illustrating the status of carrying out the first cooling-warming process on the phononic material according to Example 1 and the transition status of electrical resistance values.

FIG. 6(g) is a graph (3) illustrating the status of carrying out the first cooling-warming process on the phononic material according to Example 1 and the transition status of electrical resistance values.

FIG. 6(h) is a graph (4) illustrating the status of carrying out the first cooling-warming process on the phononic material according to Example 1 and the transition status of electrical resistance values.

FIG. 7 is a graph illustrating characteristic changes of the periodic structure body in a heat treatment (the pretreatment process) from the first cycle to the fifth cycle.

FIG. 8 is a graph in which the cycle number z′ is plotted on the horizontal axis and the 300 K resistance value R_{300K} is plotted on the vertical axis for the periodic structure body in the heat treatment from the first cycle to the fifth cycle.

FIG. 9 is a diagram schematically illustrating a transition state of the periodic structure body to a first precursor in the pretreatment process.

FIG. 10(a) is a graph illustrating the measurement results of voltage-current characteristics when direct current is applied to a second precursor.

FIG. 10(b) is a graph illustrating the measurement results of voltage-current characteristics when direct current is applied to a third precursor.

FIG. 11(a) is a graph for describing the status of carrying out a second cooling-warming process on a phononic material according to Example 1 and the transition status of electrical resistance values.

FIG. 11(b) is a partially enlarged graph in which a range of 20 K to 60 K in FIG. 11(a) is enlarged.

FIG. 12(a) is a diagram illustrating an equivalent circuit of a measuring circuit used to measure differential conductance voltage characteristics of a periodic structure body in the phononic material according to Example 1.

FIG. 12(b) is a graph illustrating the measurement results of the differential conductance voltage characteristics of the periodic structure body in the phononic material according to Example 1.

FIG. 12(c) is a graph in which FIG. 12(b) is plotted as the square of voltage on the horizontal axis.

FIG. 13(a) is a diagram illustrating an equivalent circuit of a measuring circuit used to measure capacitance-voltage characteristics of the periodic structure body in the phononic material according to Example 1.

FIG. 13(b) is a graph illustrating the measurement results of the capacitance-voltage characteristics of the periodic structure body in the phononic material according to Example 1.

FIG. 13(c) is a graph in which FIG. 13(b) is plotted as the reciprocal of the square of capacitance on the vertical axis (Mott-Schottky plot, 1/C²−V).

FIG. 14(a) is a diagram schematically illustrating a band structure at a junction interface of the junction structure in Example 1, and the status of carrier transport.

FIG. 14(b) is a schematic diagram illustrating a band structure when the voltage applied to both ends of the junction structure in Example 1 is in five voltage regions with voltage values (V=−0.85 V, −0.05 V, +1.05 V, and +1.85 V) as boundary values at four characteristic peaks illustrated in FIG. 12(b).

FIG. 15(a) is a diagram illustrating an equivalent circuit of a measuring circuit used to measure changes over time in current flowing through the junction structure in Example 1.

FIG. 15(b) is a graph illustrating the measurement results of changes over time in current flowing through the junction structure in Example 1.

FIG. 16(a) is a photo of an experimental setup.

FIG. 16(b) is a diagram illustrating an equivalent circuit of an electrical circuit for confirmation measurement, which is connected to an external electrical circuit.

FIG. 16(c) is a graph illustrating the measurement results of changes over time in voltage VL generated between both ends of a metal film resistor connected to the outside of the phononic material according to Example 1.

FIG. 16(d) is a graph illustrating changes over time in time average of energy produced by the phononic material according to Example 1.

FIG. 17(a) is a diagram illustrating an equivalent circuit of a measuring circuit used to measure voltage-pulse current characteristics.

FIG. 17(b) is a graph illustrating the measurement results of the voltage-pulse current characteristics.

### MODE FOR CARRYING OUT THE INVENTION

(Phononic Material) A phononic material of the present invention has a periodic structure body that exhibits a voltage-current characteristic to apply current when the potential gradient is 0 V.

Further, it is preferred that the phononic material should have the following characteristics together.

In other words, it is preferred that the periodic structure body should be able to supply current to an external electrical circuit when the potential gradient is 0 V.

Further, it is preferred that the periodic structure body should exhibit a voltage-current characteristic to apply current when a potential gradient is given.

Further, it is preferred that the periodic structure body should be able to supply current to the external electrical circuit when the potential gradient is given.

The external electrical circuit is not particularly limited, and a known load, wiring to connect the periodic structure body and the load, and the like can be mentioned.

A method for measuring current flowing through the periodic structure body is not particularly limited, and a known four-terminal method or a two-terminal method can be used, for example.

Further, a method for measuring current to be supplied to the external electrical circuit by the periodic structure body is not particularly limited, and a known discharge test in the battery field can be used, for example.

The characteristics of the phononic material are exhibited in the periodic structure body that has undergone a predetermined production process. In this specification, the periodic structure body as a base material that exhibits the characteristics will first be described, and the production process to make the periodic structure body exhibit the characteristics will next be described as a method for producing the phononic material.

<Periodic Structure Body>

The periodic structure body is so constructed that structures are periodically and regularly disposed in a constituent containing elements having d orbital.

The periodic structure body thus constructed is also called a phononic crystal in contrast to a normal crystal exhibiting a state in which atoms and molecules are periodically and regularly disposed in a material.

In the phononic crystal, the arrangement of the structures can be set artificially, and the setting method draws attention to phonon engineering.

In such a periodic structure body (phononic crystal), a property that the phonon group velocity and energy density become smaller than those of a constituent in a bulk state without any structures.

The degree of this property changes depending on how to arrange the structures. In other words, the phonon group velocity and energy density can be changed in the periodic structure body depending on the phonon engineering to be applied. These phonon group velocity and energy density have such a relation that when one of them becomes smaller, the other becomes smaller, and when one of them becomes larger, the other becomes larger.

The periodic structure body is not particularly limited. However, when paying attention to the phonon group velocity of the constituent in the periodic structure body, it is preferred that the phonon group velocity of the constituent in the periodic structure body should be less than or equal to ½ of the constituent in the bulk state because it is easier to control the behavior of electrons and holes in the constituent as the phonon group velocity and energy density are smaller.

The constituent is not particularly limited as long as it is a substance containing elements having d orbital, and it can be selected from among known metal materials and semiconductor materials as appropriate according to the purpose. In other words, in the phononic material, physical properties different from the physical properties intrinsic to the constituent are acquired by using a phenomenon in which phonons in the constituent interact with electrons in the constituent during heat treatment by cooling and warming, but the phenomenon can occur in any substance. This is because phonons always exit as long as it is a substance. On the other hand, the constituent must be a substance containing elements having d orbital. This is because the properties can be developed by interaction between electrons in d orbital and phonons.

Above all, as the constituent, a substance containing a transition metal element (an element belonging to group 3 to group 12) is preferred, and a substance constructed as a single substance of the transition metal element is particularly preferred.

The transition metal element is not particularly limited, but an element with vacancy in d orbital is preferred, and when the constituent contains the transition metal element without vacancy in d orbital, it is preferred to be constructed as an alloy or a semiconductor compound.

Further, it is preferred to be selected from superconducting substances that exhibit the properties of a superconductor in the bulk state. In other words, use of a substance originally having the properties of the superconductor makes it easier to build a new material order to give properties as the superconductor to the periodic structure body.

The structures are not particularly limited, and can be selected according to the purpose, such as structures applied to a known phononic crystal.

Above all, when the periodic structure body is formed in a layer, it is preferred that the structures should be through holes pierced in a thickness direction of the layer. When the structures are formed as the through holes, the periodic structure body can be produced by known lithography, and this makes it easier to stably obtain a group of the structures regularly disposed in the periodic structure body. Further, when the structures are formed as the through holes, a filling substance formed of a different material from the constituent may be filled in the through holes to adjust the phonon group velocity and energy density.

Note that a case where the periodic structure body is constructed by repeatedly disposing unit structure bodies, each of which is constructed of plural structures with different shapes, is included as the periodic structure body in addition to the case where the periodic structure body is constructed by repeatedly disposing structures of the same shape.

The period to form the structures in the periodic structure body, that is, the interval between adjacent two of the structures may be any period in a phonon wavelength scale (for example, in a scale from the order of nanometers to the order of millimeters (1 nm to 10 mm)), and when the period is such a period, the phonon group velocity and energy density of the constituent in the periodic structure body become smaller than those of the constituent in the bulk state.

Further, the size of each of the structures may also be any size in the phonon wavelength scale (for example, in the scale from the order of nanometers to the order of millimeters (1 nm to 10 mm)), and when the size is such a size, the phonon group velocity and energy density of the constituent in the periodic structure body become smaller than those of the constituent in the bulk state.

Note that the size of each of the structures corresponds to the maximum diameter of the structure. For example, in the case of the through hole, when the opening diameter is larger than the depth thereof, the size corresponds to the opening diameter, and when the length has a shape larger than the width in the opening diameter, the size corresponds to the length.

Further, in such an aspect that the periodic structure body is formed in a layer and the structures are the through holes pierced in the thickness direction of the layer as described as a preferred form of the periodic structure body, when the conditions below are further met, it is further easier to build a new material order to give properties as a superconductor to the periodic structure body.

In other words, it is preferred that the opening diameter of each of the through holes should be 1 nm to 10 mm, and it is more preferred that it should be 10 nm to 1 mm.

Further, it is preferred that the interval between adjacent two through holes should be 1 nm to 0.1 mm, and it is more preferred that it should be 10 nm to 0.01 mm.

Further, it is preferred that the layer thickness of the periodic structure body should be 0.1 nm to 0.01 mm, and it is more preferred that it should be 1 nm to 0.001 mm.

Note that the periodic structure body is not particularly limited, which may be produced by a known method for producing a phononic crystal, or a known phononic crystal produced in advance may be used.

### EMBODIMENT

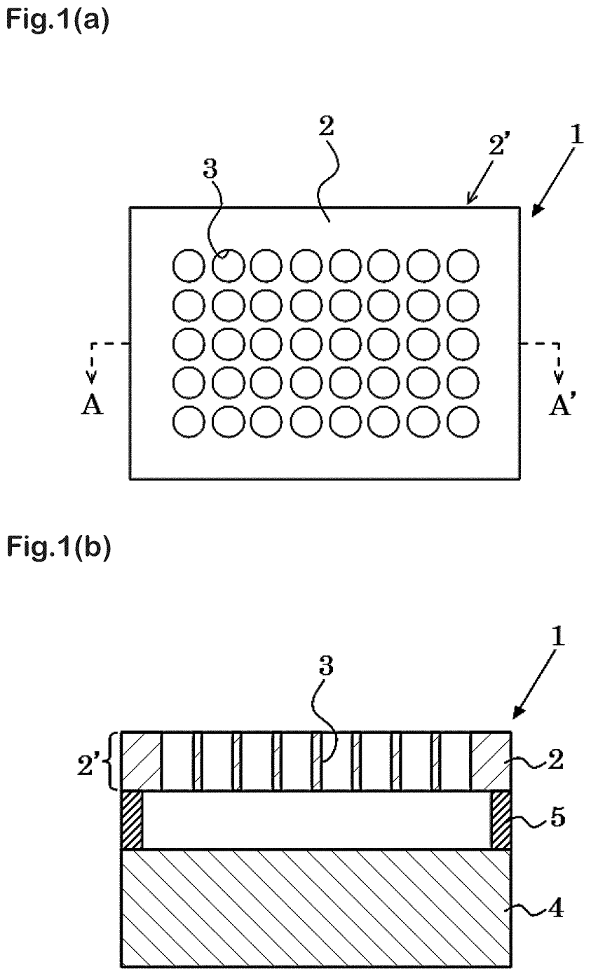

A phononic material according to an embodiment of the present invention will be described with reference to the accompanying drawings. FIG. 1(a) is an explanatory drawing illustrating the top surface of a phononic material according to one embodiment of the present invention, and FIG. 1(b) is an explanatory drawing illustrating an A-A′ line section in FIG. 1(a).

As illustrated in FIG. 1(a) and FIG. 1(b), a phononic material 1 has a periodic structure body 2′ in which cylindrical through holes as structures 3 are periodically and regularly disposed in a constituent 2.

The periodic structure body 2′ is placed on a substrate 4 through spacers 5. The spacers 5 are placed to support the periodic structure body 2′ at the outer peripheral positions of a region in which the structures 3 are formed. The substrate 4 and the spacers 5 are provided to measure property changes of the periodic structure body 2′ during cooling and warming, and a region on the side of the bottom of the periodic structure body 2′ (the surface on the side of the substrate 4) in which the structures 3 are formed is made hollow to be able to measure property changes of the periodic structure body 2′ without being affected by phonons existing in this region.

Further, the substrate 4 is made of a material such as Si used in general microfabrication from the point of view of producing such a structure. Further, from the point of view of performing such a measurement, the spacers 5 are made of an electrically insulating material such as SiO₂.

Note that the substrate 4 and the spacers 5 can be removed before or after the properties are exhibited in the periodic structure body 2′ to make the periodic structure body 2′ itself as a phononic material.

The periodic structure body 2′ illustrated in FIG. 1(a) and FIG. 1(b) is an example for description, and the settings of each of the structures 3, the number of formations, the arrangement thereof, and the like can be selected as appropriate according to the purpose.

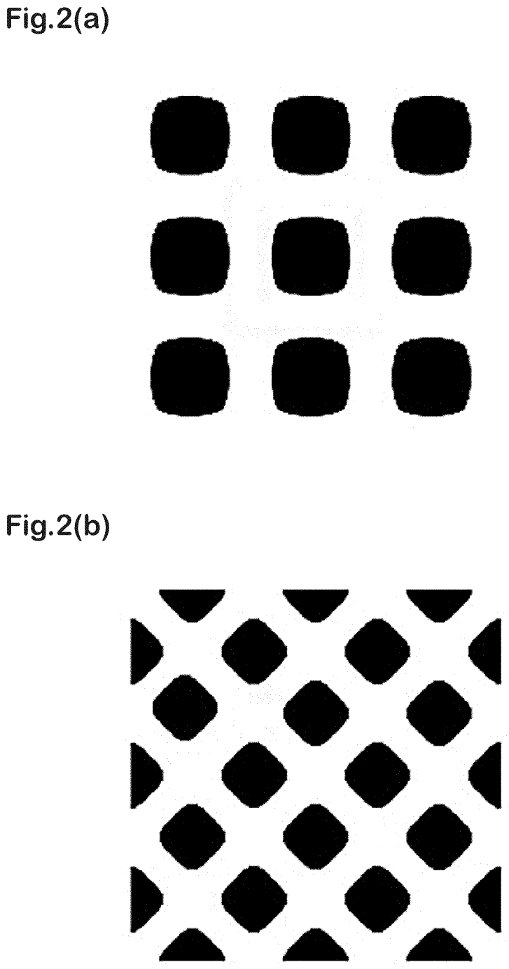

Modifications of the structures 3 are illustrated in FIG. 2(a) to FIG. 2(d). Note that FIG. 2(a) to FIG. 2(d) are diagrams (1) to (4) illustrating the modifications of the structures, respectively.

In the example illustrated in FIG. 2(a), the structures are formed as substantially square columnar through holes. Further, in the example illustrated in FIG. 2(b), the regularity of disposing the through holes illustrated in FIG. 2(a) is changed.

Even in the periodic structure body having these structures, such properties that the phonon group velocity and energy density become smaller than those of the constituent in the bulk state can be obtained as the phononic crystal.

In FIG. 2(c) and FIG. 2(d), examples in which the periodic structure body is constructed by repeatedly disposing unit structures, each of which is constructed of plural structures with different shapes, are illustrated.

Even in the periodic structure body in which the unit structures are formed as the structures, such properties that the phonon group velocity and energy density become smaller than those of the constituent in the bulk state can be obtained as the phononic crystal.

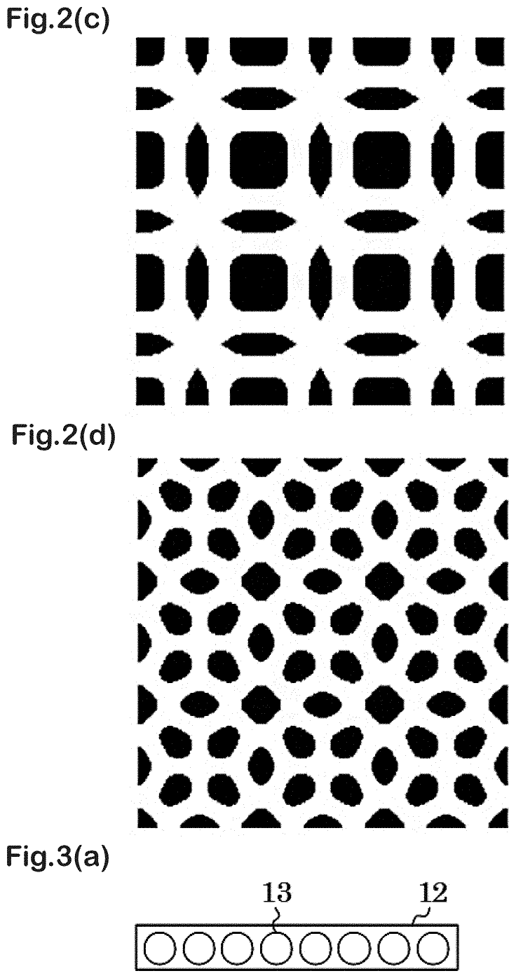

Further, in the periodic structure body 2′ illustrated in FIG. 1(a) and FIG. 1(b), the arrangement of the structures 3 is a two-dimensional arrangement with periodicity in the width and length directions of the periodic structure body 2′ especially as illustrated in the top view of FIG. 1(a), but the arrangement may also be a one-dimensional arrangement or a three-dimensional arrangement (see FIG. 3(a) to FIG. 3(c)). Note that FIG. 3(a) is an explanatory drawing illustrating a configuration example of a one-dimensional phononic material, FIG. 3(b) is an explanatory drawing (1) illustrating a configuration example of a three-dimensional phononic material, and FIG. 3(c) is an explanatory drawing (2) illustrating a configuration example of a three-dimensional phononic material.

In other words, in a periodic structure body 12 illustrated in FIG. 3(a), the arrangement of structures 13 is a one-dimensional arrangement with periodicity in the length direction of the periodic structure body 12.

Further, in a periodic structure body 22 illustrated in FIG. 3(b), which is formed in a similar manner to the periodic structure body 2′ illustrated in FIG. 1(a) and FIG. 1(b), the arrangement of structures 23a and 23b is a tree-dimensional arrangement with periodicity in the thickness direction in addition to the width and length directions of the periodic structure body 22 by laminating, in the thickness direction of the periodic structure body 22, a layer of a constituent 22a with the structures 23a formed therein and a layer of a constituent 22b with the structures 23b formed therein. Note that reference numeral 24 in FIG. 3(b) indicates a substrate and reference numeral 25 indicates spacers.

Further, in a periodic structure body 22′ illustrated in FIG. 3(c), unit structures each of which is a cubic block region 26 with circular holes as structures 23′ formed on respective sides are constructed to have three-dimensional periodic arrays in which plural unit structures are combined in the height direction and the width and length directions of the periodic structure body 22′. Note that the periodic structure body 22′ can be produced by a known 3D printer or the like.

(Production Method of Phononic Material) A production method of a phononic material of the present invention is a method for producing the phononic material of the present invention, which includes a pretreatment process, a first cooling-warming process, a current application process, and a second cooling-warming process.

<Pretreatment Process>

The pretreatment process is a process to obtain a first precursor as the periodic structure body that does not develop a bifurcation phenomenon by performing a heat treatment to warm the periodic structure body up to a temperature exceeding a bifurcation temperature after cooling the periodic structure body up to a temperature lower than the bifurcation temperature in a state of applying a unidirectional current to the periodic structure body until the bifurcation phenomenon disappears, where the bifurcation phenomenon is a phenomenon in which, when a cooling resistance temperature characteristic of the periodic structure body in a cooling process of continuous heat cycles to raise temperature after cooling the periodic structure body is compared with a warming resistance temperature characteristic of the periodic structure body in a warming process, the warming resistance temperature characteristic bifurcates from the cooling resistance temperature characteristic to exhibit a high electrical resistance value at a common temperature, and the bifurcation temperature is a temperature at which the cooling resistance temperature characteristic and the warming resistance temperature characteristic bifurcate each other in the bifurcation phenomenon.

In the periodic structure body, the bifurcation phenomenon in which, when the cooling resistance temperature characteristic of the periodic structure body in the cooling process of continuous heat cycles to raise temperature after cooling the periodic structure body is compared with the warming resistance temperature characteristic of the periodic structure body in the warming process, the warming resistance temperature characteristic bifurcates from the cooling resistance temperature characteristic to exhibit a high electrical resistance value at a common temperature is developed.

In the periodic structure body in the state of developing this phenomenon, since electrons remain itinerant in the constituent and the interaction between electrons is not strengthened to the extent that the electrons are localized, it is hard to give properties as a superconductor to the periodic structure body to be described in the next process.

Therefore, the pretreatment process is carried out to make the electrons in the constituent localized strongly until the electrons in the constituent cannot itinerate in order to make the bifurcation phenomenon not to be developed.

Here, a state of localizing the electrons in d orbital during the pretreatment process can be observed as the Friedel sum rule (see Reference Document 1, pp. 50-57, below). In general, the Friedel sum rule describes such a phenomenon that, when a different transition metal element is mixed as an impurity in a maternal transition metal, resistance R rises to satisfy the relationship of R∝sin²(z×π/10) according to a difference z in valence. Since the number of d orbitals is five and two spin-up and spin-down electrons can go into each orbital in total, 10 electrons can be localized to occupy the d orbitals at the maximum.
Reference Document 1: Postgraduate Condensed Matter Physics II, Strongly Correlated Electron System, supervised by Muneyuki Date, Kodansha Ltd. (1997)

In the periodic structure body, the electrons of the constituent are localized one by one in d orbital each time the heat treatment is repeated in the pretreatment process as if it were growing as a material different from the constituent of the base material. The state is observed as a resistance increase to satisfy the relationship of R∝sin²(z′×π/10) when the resistance is denoted by R and the number of heat treatment processes is denoted by z′.

For example, when the constituent is niobium, the d orbitals are occupied by four to five electrons under normal conditions, and there are five to six vacant spaces. Therefore, in the periodic structure body using niobium as the constituent, the pretreatment process containing five to six times of the heat treatment is carried out to localize the electrons in the constituent in a manner to occupy the d orbitals completely. Note that when two electrons are localized in each d orbital, the pretreatment process is carried out about three times (R∝sin²(2z′×π/10)).

Here, when the electrons supplied into the constituent are not spatially uniform, Anderson localization to localize the electrons due to the spatial disturbance becomes apparent. In other words, in this case, the transition of the periodic structure body to the insulator is made at once without observing such a state that one or two electrons occupy each d orbital (see Non-Patent Document 4). It is important for the first precursor to localize the electrons in the constituent in order to occupy the d orbitals completely, and the Anderson-type insulator cannot obtain properties as the superconductor in the first cooling-warming process as the next process.

In contrast, in the pretreatment process, electrons are supplied into the constituent spatially uniformly by applying the unidirectional current to the periodic structure body. As a specific method, there is a method in which a sample with the periodic structure body formed therein is cut out into a plate shape (one-dimension or two-dimension) or a column shape (three-dimension), and respective ends of the sample as electrodes are connected to a current source to apply current from one end side to the other end side. In other words, the electrons can be supplied into the constituent spatially uniformly as long as the paths of the current flowing through the periodic structure body are restricted in the same direction.

Note that the current applied to the periodic structure body is not particularly limited, which can be either a direct current or a square wave current.

In the periodic structure body that has undergone the pretreatment process, it is inferred from empirical results in examples to be described later that electrons localized in d orbitals in the constituent interact with phonons according to the positional relationship between the structures and the constituent has such a structure that parts (Mott-insulating parts) that allow metal-Mott insulator transitions (see Reference Document 2 below) and the other parts, that is, parts (conducting parts) in which electrons and holes intrinsic to the constituent can itinerate freely are arranged regularly according to the structure of the periodic structure body.
Reference Document 2: Metal-Insulator Transitions (Second Edition), by Nevill F. Mott, Maruzen Publishing Co., Ltd. (1996)

Although the mechanism to develop high-temperature superconductivity has not been academically settled yet, a high-temperature superconductor typified by YBCO or BSCCO is a three-dimensional periodic structure body in which conductive layers composed of copper oxide and insulating layers are regularly laminated. In this respect, since the periodic structure body after going through the pretreatment process also has the structure that the conducting parts and the Mott-insulating parts are regularly arranged, there is a structural similarity.

On the other hand, there is a difference in lattice constant scale between the high-temperature superconductor and the periodic structure body. The former arrangement interval is in an atomic scale order, which is the order of sub-nanometers. On the other hand, the latter arrangement interval is in a phonon wavelength scale (for example, in a scale from the order of nanometers to the order of millimeters (1 nm to 10 mm)). In the discussion of a crystal structure in Chapter 1 of Introduction to Solid State Physics goes on from the tacit fact that the lattice constant is in the atomic scale, but the discussion of the crystal structure does not depend on the magnitude of the lattice constant as a matter of fact (see Reference Document 3, pp. 1-11, below). This is why the phononic material is also called a phononic crystal. In other words, the first precursor is a macro-scale crystal composed of the conducting parts and the Mott-insulating parts.

In the meantime, the high-temperature superconductor is made originally as a result of a superconducting phase transition by doping carriers such as electrons and holes into a material originally having an antiferromagnetic phase such as the Mott-insulator. The act of increasing the dopant concentration of carriers done there is nothing but an act to increase a quantum mechanical probability t of the carriers to jump from one conductive layer to an adjacent conductive layer across the insulating layer so as to weaken a repulsive interaction U between electrons because it is originally the Mott-insulator. In other words, the properties as a superconductor are developed by giving a good balance between the quantum mechanical probability t and the repulsive interaction U between electrons.

From another point of view, the high-temperature superconductor can be regarded as a collection of tunnel junctions that repeat arrays of conductive layer-insulating layer-conductive layer-insulating layer-conductive layer . . . , and the power storage states of respective tunnel junctions are well balanced by increasing the dopant concentration of carriers to form a superconductor. In fact, the high-temperature superconductor is also called an intrinsic Josephson junction, and a critical current value as a maximum applied current value at which the high-temperature superconductor can preserve the properties as the superconductor can be explained by an Ambegaokar-Baratoff relational expression as an expression to give a critical current value of the Josephson junction (see Reference Document 4 below).
Reference Document 3: Introduction to Solid State Physics (Seventh Edition), by Charles Kittel, Maruzen Publishing Co., Ltd. (1998)
Reference Document 4: R. Kleiner et al., Phys. Rev. B 49, 1327 (1994)

Here, the Ambegaokar-Baratoff relational expression is represented by Equation (1) below, where the critical current value is denoted by I_{C}, the metallic resistance value is denoted by Rn, the superconducting energy gap in the superconducting state is denoted by A, the temperature is denoted by T, the elementary charge is denoted by e, and the Boltzmann constant is denoted by k_{B}.

$$\begin{matrix}[ Math . 1 ] & \\ {I}_{C} = \frac{Δ}{2 {eR}_{n}} tanh ( \frac{Δ}{2 {k}_{B} T} ) & ( 1 )\end{matrix}$$

When the same idea as the high-temperature superconductor is also introduced into the first precursor, the first precursor can be regarded as a collection of tunnel junctions in which tunnel junctions, each composed of the conducting part-the Mott-insulating part-the conducting part, are regularly disposed. In the first cooling-warming process as the next process, when the power storage state of each tunnel junction is well balanced, the intrinsic Josephson junction is formed just like the high-temperature superconductor, and the Ambegaokar-Baratoff relational expression is satisfied to develop the properties as the superconductor.

Note that the “superconductor” generally exhibits zero resistance, but the periodic structure body may exhibit an electrical resistance value less than 0Ω according to the present invention. In this specification, the characteristic to exhibit the electrical resistance value less than 0Ω is treated as the “superconductor” as a whole.

Although the cooling and warming speed in the pretreatment process is not particularly limited, it is preferred to be 1 K/min or less because it is easy to localize electrons in d orbitals in the constituent. Note that the lower limit of the speed is about 0.01 K/min in terms of efficiency.

The cooling temperature in the pretreatment process is not particularly limited as long as it is a temperature lower than the bifurcation temperature, and the cooling temperature can be set, for example, to a temperature about 20 K lower than the bifurcation temperature.

Further, the warming temperature in the pretreatment process is not particularly limited as long as it is a temperature exceeding the bifurcation temperature, and the warming temperature can be set, for example, to a temperature about 40 K higher than the bifurcation temperature.

Further, when the pretreatment process is performed in a wide temperature range, a temperature of 2 K or lower (lower limit: about 10 mK) may be set as the cooling temperature (lowest temperature), and a temperature of 300 K or higher (upper limit: about 400 K) may be set as the warming temperature (highest temperature).

Equipment to carry out the pretreatment process is not particularly limited, and a known refrigerant Dewar or refrigerator can be used, for example.

Note that, when the bifurcation temperature is different between heat treatment cycles of cooling and warming and it is confirmed as a wide temperature zone, cooling is performed at a temperature lower than this temperature zone and warming is performed at a temperature higher than this temperature zone.

<First Cooling-Warming Process>

The first cooling-warming process is a process to carry out a heat treatment on the first precursor to warm the first precursor up to a temperature exceeding the bifurcation temperature after cooling the first precursor up to a temperature lower than the bifurcation temperature until the warmed first precursor exhibits an electrical resistance value of 0Ω or less in order to obtain a second precursor as the periodic structure body having an electrical resistance characteristic that exhibits an electrical resistance value less than or equal to 0Ω in a temperature range exceeding the bifurcation temperature.

Note that there is a need to measure the electrical resistance value of the first precursor to carry out the first cooling-warming process. As the measuring method, for example, there is a method of measuring an electrical resistance value for current using a known four-terminal method or the like while adopting the current application conditions adopted in the pretreatment process.

The cooling temperature in the cooling process is not particularly limited as long as it is a temperature lower than the bifurcation temperature, but it is preferred to be a temperature of 2 K or less from the perspective of giving the properties as the superconductor to the periodic structure body with a small number of cycles. Note that the lower limit of the cooling temperature is about 10 mK.

Further, the warming temperature in the warming process is not particularly limited as long as it is a temperature exceeding the bifurcation temperature, but it is preferred to be a temperature of 300 K or more from the perspective of giving the properties as the superconductor to the periodic structure body with a small number of cycles. Note that the upper limit of the warming temperature is about 400 K.

As equipment to carry out the first cooling-warming process, the same equipment as the equipment to carry out the pretreatment process can be used, and a known refrigerant Dewar or refrigerator can be used, for example.

Note that the lower speed limit of the cooling process and the warming process is not particularly limited, but it is about 0.01 K/min from the perspective of performing the heat treatment efficiently.

Further, in the first cooling-warming process, the bifurcation temperature confirmed in the pretreatment process is different between heat treatment cycles of cooling and warming, and in the case of a wide temperature zone, cooling is performed at a temperature lower than this temperature zone and warming is performed at a temperature higher than this temperature zone.

<Current Application Process>

The current application process is a process to apply, to the second precursor, the same unidirectional current or a current in the opposite direction with a magnitude of a critical current value or more that loses the electrical resistance characteristic in order to obtain a third precursor as the periodic structure body that does not exhibit the electrical resistance characteristic.

The application of the current of the critical current value or more to the second precursor can make some of electrons, localized to occupy the d orbitals in the second precursor completely, ripped away forcibly. In other words, holes can be injected into the second precursor without going through a production process using high energy such as diffusion bonding, alloy diffusion, or ion implantation method as a typical method for producing the pn junction in conventional technology.

Thus, in the third precursor, properties as a semiconductor having excessive holes in part of the periodic structure body are developed.

The temperature at which the current application process is carried out is not particularly limited, and it is in a temperature range exceeding the bifurcation temperature at which the second precursor exhibits properties as the superconductor. Above all, it is preferred to be a temperature of 273 K or more from the perspective of ease of carrying out the process. Note that the upper limit is about 400 K.

Equipment to carry out the current application process is not particularly limited, and a known current source or a source/measure unit can be used, for example.

Note that, as a current application method in the current application process, there is the method described in the pretreatment process, and the current application direction is the same direction as the current application direction in the pretreatment process or a direction opposite thereto from the perspective of maintaining the properties developed in the first precursor. This current application method in the current application process includes the application of current in the same direction as the current application direction in the pretreatment process while changing the polarity of the current.

<Second Cooling-Warming Process>

The second cooling-warming process is a process to carry out a heat process on the third precursor to warm the third precursor up to a temperature exceeding the bifurcation temperature after cooling the third precursor up to a temperature lower than the bifurcation temperature until the third precursor exhibits a voltage-current characteristic to make current flow when the potential gradient is 0 V.

The second cooling-warming process is a process to recover the properties as the superconductor lost by the current application process, which can be carried out in the same manner as the first cooling-warming process to give the properties as the superconductor.

In the periodic structure body after going through the second cooling-warming process, the properties as the superconductor are recovered.

However, unlike the second precursor, the periodic structure body after going through the second cooling-warming process develops such a property as to exhibit a voltage-current characteristic to make current flow when the potential gradient is 0 V.

In the periodic structure body after going through the second cooling-warming process, this phenomenon results in the fact that parts with the properties as the superconductor recovered by going through the previous current application process, and parts having properties as the semiconductor with excessive holes acquired in the current application process are periodically formed according to the periodic array of the structures, and hence junctions of these parts are periodically formed in the periodic structure body.

At the same time, this phenomenon means that the depletion layer is formed in the vicinity of the junctions formed in the periodic structure body, and that a built-in electric field accompanied by the carrier diffusion is generated.

In other words, since there is no cause to impair the properties as the superconductor unlike the pn junction produced using high energy in the conventional technology, and there is no cause to suppress the carrier diffusion unlike the junction in which the third solid is inserted between the semiconductor and the superconductor, this phenomenon suggests that acceleration motion is given to carriers by the depletion layer and the built-in electric field formed in the second cooling-warming process in the periodic structure body after going through the second cooling-warming process, and the Andreev reflection can occur spontaneously even when the potential gradient is 0 V.

In the second cooling-warming process, the voltage-current characteristic of the periodic structure body after going through the process becomes a concern unlike in the first cooling-warming process. However, since this voltage-current characteristic is exhibited in association with the electrical resistance characteristic given by the first cooling-warming process, the second cooling-warming process can be carried out until the warmed periodic structure body exhibits the electrical resistance value of 0Ω or less while measuring the electrical resistance value of the periodic structure body like in the first cooling-warming process. But it may also be carried out while checking if the warmed periodic structure body exhibits the voltage-current characteristic.

### EXAMPLE

### Example 1

A phononic material according to Example 1 was produced as follows. First, using a CVD system (PD-270STL made by Samco Inc.), a silicon oxide layer was formed with a thickness of 1 μm on a silicon wafer substrate (made by Miyoshi LLC; a diameter of 76.0 mm, an orientation of (100)±1°, P-type, mirror-finished surface, backside etching finish, and particles of 0.3 μm or more, whose number is ten or less).

Next, using sputtering equipment (M12-0130 made by Science Plus Co., Ltd.), a niobium layer was formed with a thickness of 150 nm on the silicon oxide layer.

Next, after forming an i-line lithography resist layer on the niobium layer using a resist coater (SK-60BW-AVP made by Dainippon Screen Mfg. Co., Ltd.), i-line lithography using a mask having a mask pattern in which holes having the same structure as a target periodic structure body were pierced was performed by i-line lithography equipment (NSR-2205i12D made by Nikon Tec Co., Ltd.) to process the resist layer into a resist pattern with the mask pattern transferred.

Next, etching processing was performed on the niobium layer through the resist pattern by a reactive ion etching system (RIE-10NR made by Samco Inc.) using SF₆ as a reaction gas to form, as a periodic structure body having the periodic structure, the niobium layer having a structure in which regions (structures) having cylindrical through holes of the same shape are regularly and periodically disposed.

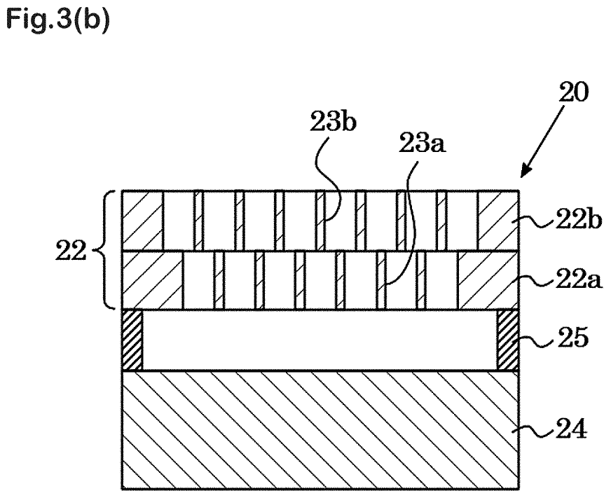

Here, the state of the niobium layer on the silicon wafer substrate is illustrated in FIG. 4. Note that FIG. 4 is an explanatory drawing illustrating a state of the niobium layer as viewed from the top.

As illustrated in FIG. 4, a niobium layer 32 has such a structure that through holes 33 (a group indicated by black circles in the figure) are pieced in the thickness direction.

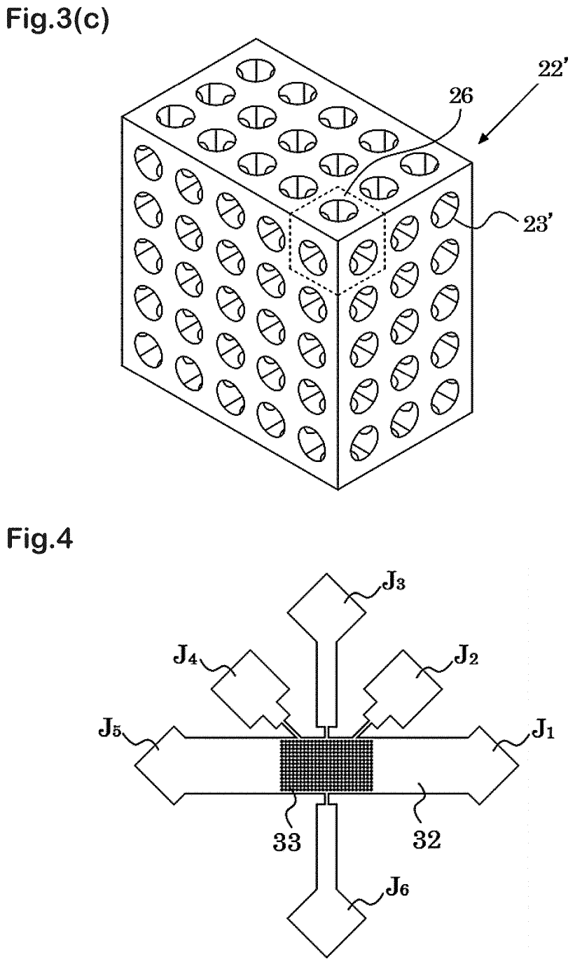

Further, in more detail, the niobium layer 32 has a structure in which 350 rectangular block regions 36 each of which is illustrated in FIG. 5 are formed. Note that FIG. 5 is an explanatory drawing illustrating each of the rectangular block regions when the niobium layer is viewed from above.

In the rectangular block region 36, a through hole 33 with a diameter d of 19.7 μm is pierced at the center.

Further, distance s between the outer circumference of the through hole 33 and the closest perimeter of the rectangular block region 36 is set to 150 nm. In other words, the niobium layer 32 as the periodic structure body has a structure in which the through holes 33 as structures are regularly and periodically disposed at intervals of 300 nm.

Further, a crystal structure when a portion in which the through holes 33 of the niobium layer 32 are formed is viewed as a phononic crystal is a square lattice, and the lattice constant is 20 μm. Note that the square lattice means such a structure that the through holes 33 are arranged on the niobium layer 32 in a square lattice shape from the top view, and the lattice constant means a distance between the center of one unit lattice and the center of any other adjacent unit lattice when each of the rectangular block regions 36 is a unit lattice.

The structure of the periodic structure body illustrated in FIG. 4 is formed based on the mask shape settings.

Next, the silicon wafer substrate in this state was cut to have the niobium layer in the center.

Next, using dry etching equipment (memsstar SVR-vHF made by Canon Inc.), HF gas was brought into contact with the silicon oxide layer under the niobium layer through the through holes to perform dry etching processing to partially remove the silicon oxide layer.

Here, sections of the silicon oxide layer located under the sections of the niobium layer 32 in which no through hole 33 is formed in FIG. 4 remain after the dry etching processing to play a role in supporting the niobium layer 32 while making sections under the sections with the through holes 33 formed into a hollow state.

Thus, the sample body of Example 1 was produced.

Next, a pretreatment process and a first cooling-warming process to be described below were carried out on the sample body of Example 1, and a measurement test of the electrical resistance of the periodic structure body obtained by these processes was performed.

First, a four-terminal resistance measuring device (P102 made by quantum Design Japan, Inc.) was connected to the sample body of Example 1 to measure the electrical resistance of the periodic structure body.

Specifically, terminals I+, I−, V+, V− of the four-terminal resistance measuring device were connected respectively to terminals J₁, J₅, J₂, J₄ in FIG. 4 to measure the electrical resistance of the periodic structure body by reading the potential difference between the terminals J₂ and J₄ while applying current between the terminals J₁ and J₅.

Here, the application of the current between the terminals J₁ and J₅ is to restrict the paths of current flowing through the periodic structure body in the same direction in order to supply electrons spatially uniformly into the constituent between the structures.

Next, the sample body of Example 1 was put in a physical property measuring device (PPMS made by quantum Design Japan, Inc.), the magnitude of the magnetic field in the physical property measuring device was so set that a magnetic flux density penetrating the sample body vertically became 10 uT or less, and the pretreatment process and the first cooling-warming process, in which a cooling-warming heat treatment was one cycle, were carried out under an atmosphere of helium gas of about 200 Pa to obtain the first precursor and the second precursor.

As a method of measuring the electrical resistance inside the physical property measuring device in more detail, the physical property measuring device was set to “AC DRIVE MODE” and “STANDARD CALIBRATION MODE” was selected to make the measurement.

More specifically, a square wave that reverses positive and negative in a cycle of 8.33 Hz was applied between the terminals J₁ and J₅ in FIG. 4 25 times at each temperature at which the electrical resistance measurement was made, and voltage generated between the terminals J₂ and J₄ for the square wave current last applied was read to determine the electrical resistance of the periodic structure body. The application of the square wave current that reverses positive and negative in this way can minimize the output voltage offset error. Note that the amplitude of the applied square wave current is always ±10 μA during the pretreatment process and the first cooling-warming process.

The details of the pretreatment process and the first cooling-warming process are illustrated in Table 1 below. Note that “Fixed Point” in the table indicates that the electrical resistance was measured after each set temperature was stabilized, and “Sweep” indicates that the electrical resistance was measured while sweeping the temperature up to a target temperature set as a target.

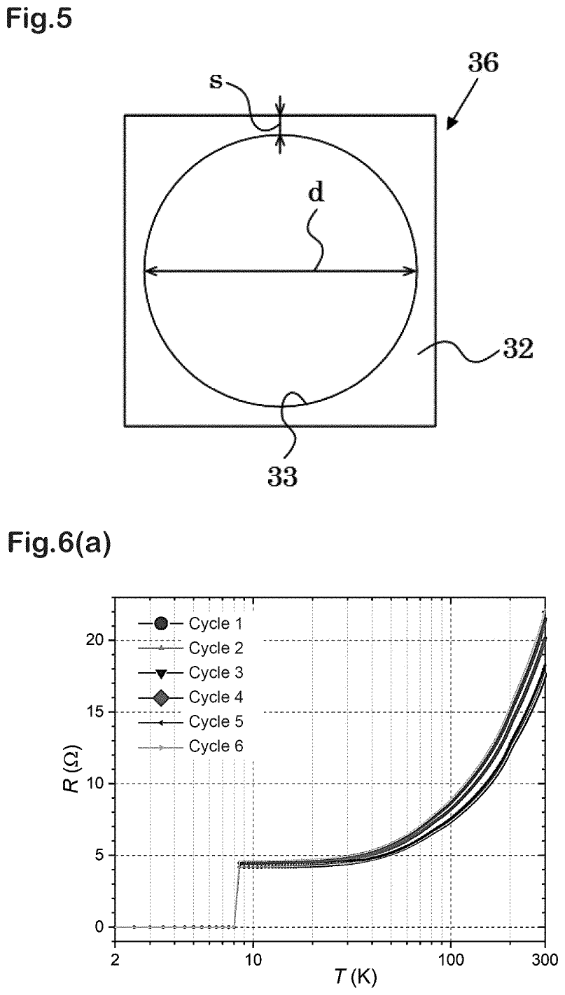

Further, the status of carrying out the pretreatment process and the first cooling-warming process on the phononic material according to Example 1 and the transition status of electrical resistance values are illustrated in FIG. 6(a) to FIG. 6(h). Note that FIG. 6(a) is a graph for describing the status of carrying out the pretreatment process on the phononic material according to Example 1 and the transition status of electrical resistance values, FIG. 6(b) is a partially enlarged graph in which a range of 20 K to 60 K in FIG. 6(a) is enlarged, FIG. 6(c) is a partially enlarged graph in the first cycle, FIG. 6(d) is a partially enlarged graph in the sixth cycle, and FIG. 6(e) to FIG. 6(h) are graphs (1) to (4) illustrating the status of carrying out the first cooling-warming process on the phononic material according to Example 1 and the transition status of electrical resistance values.

TABLE 1

| | | Starting | | |
|---|---|---|---|---|
| | | Temperature~ | Cooling/ | Timing of |
| | | Target | Warming | Electrical |
| Cycle | Process | Temperature | Speed | Resistance |
| Number | Name | (K) | (K/min) | Measurement |
| 1-5 | Pretreatment | 300-60 | 1.00 | Sweep |
| | Process | 60-2 | 0.50 | Fixed Point |
| | | 2-60 | 0.50 | Fixed Point |
| | | 60-300 | 1.00 | Sweep |

Disappearance of Bifurcation Phenomenon

| | | | | |
|---|---|---|---|---|
| 6-11 | First Cooling/ | 300-60 | 1.00 | Sweep |
| | Warming Process | 60-2 | 0.50 | Fixed Point |
| | | 2-60 | 0.50 | Fixed Point |
| | | 60-300 | 1.00 | Sweep |
| 12-13 | First Cooling/ | 300-2 | 1.00 | Sweep |
| | Warming Process | 2-300 | 1.00 | Sweep |
| 14-21 | First Cooling/ | 300-2 | 2.00 | Sweep |
| | Warming Process | 2-300 | 2.00 | Sweep |
| 22 | First Cooling/ | 300-2 | 2.00 | Sweep |
| | Warming Process | 2-230 | 2.00 | Sweep |
| | | 230-300 | 5.00 | Sweep |
| 23-24 | First Cooling/ | 300-2 | 5.00 | Sweep |
| | Warming Process | 2-300 | 5.00 | Sweep |
| 25 | First Cooling/ | 300-50 | 1.00 | Sweep |
| | Warming Process | 50-25 | 0.25 | Fixed Point |
| | | 25-2 | 0.50 | Sweep |
| | | 2-25 | 0.50 | Sweep |
| | | 25-50 | 0.25 | Fixed Point |
| | | 50-300 | 1.00 | Sweep |

Superconductivity

As illustrated in FIG. 6(a) to FIG. 6(d), in the heat treatment (the pretreatment process) of the first to fifth cycles, the bifurcation phenomenon in which the warming resistance temperature characteristic bifurcates from the cooling resistance temperature characteristic to exhibit a high electrical resistance value at a common temperature was confirmed, and the bifurcation temperature was confirmed in a temperature range of 25 K to 27 K. When the temperature rose by 10 K, the bifurcation phenomenon is observed significantly as an increase in the electrical resistance value of the warming resistance temperature characteristic by 20 mΩ or more at the common temperature. On the other hand, in the heat treatment of the sixth cycle, the warming resistance temperature characteristic transitioned to trace the cooling resistance temperature characteristic, and the cooling resistance temperature characteristic and the warming resistance temperature characteristic matched with each other. In other words, the bifurcation phenomenon disappeared by the heat treatment from the first cycle to the fifth cycle.

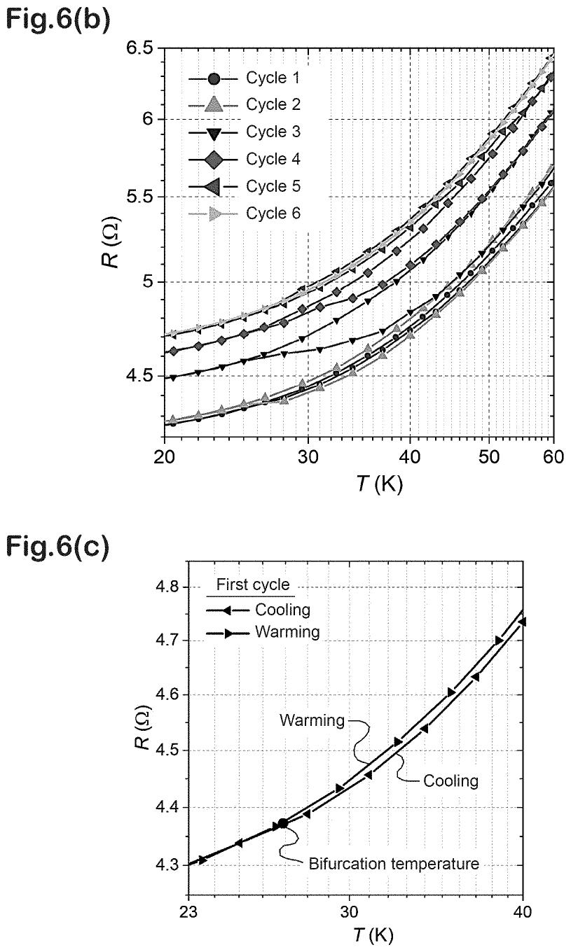

As illustrated in FIG. 7, characteristic changes of the periodic structure body in the heat treatment (the pretreatment process) from the first cycle to the fifth cycle can be confirmed as a significant resistance rise at 300 K. Note that FIG. 7 is a graph illustrating characteristic changes of the periodic structure body in the heat treatment (the pretreatment process) from the first cycle to the fifth cycle. Note that only the warming resistance temperature characteristic is illustrated for the heat treatment from the second cycle to the fifth cycle.

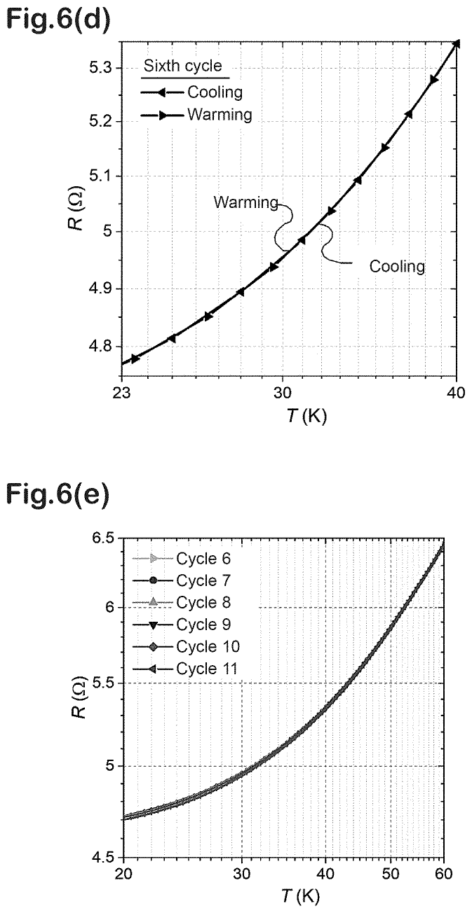

Further, a graph in which the cycle number z′ is plotted on the horizontal axis and the 300 K resistance value R_{300K} is plotted on the vertical axis for the periodic structure body in the heat treatment from the first cycle to the fifth cycle is illustrated in FIG. 8. Note that R_{300L} of z′=0 in FIG. 8 is the electrical resistance value (17.5Ω) at 300 K immediately before carrying out the heat treatment in the first cycle.

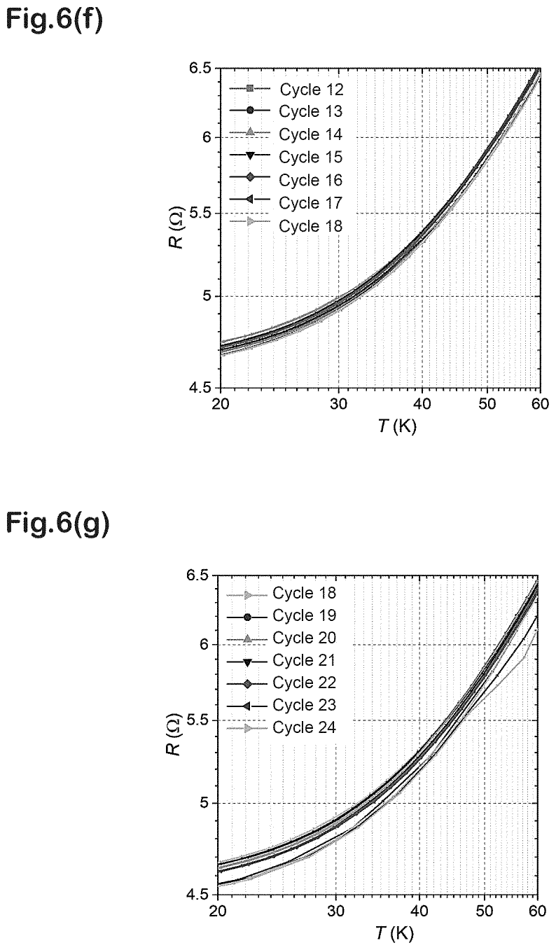

As illustrated in FIG. 8, R_{300K} is proportional to sin²(z′×π/10). This matches perfectly with the results inferred from the Friedel sum rule, and indicates that the first precursor, in which electrons were localized and d orbitals were completely occupied through the pretreatment process, was formed. A transition state of the periodic structure body to the first precursor in the pretreatment process is schematically illustrated in FIG. 9.

Next, as illustrated in FIG. 6(e) to FIG. 6(h), in the heat treatment (the first cooling-warming process) after the sixth cycle, such a situation that the resistance temperature characteristics move up and down as a whole each time the heat treatment is repeated was confirmed, though the bifurcation phenomenon was not observed. During this time, it is considered that the power storage states of respective tunnel junctions that construct the first precursor are being well balanced to most stabilize the energy of the entire periodic structure body.

Then, as illustrated in FIG. 6(h), it was confirmed that the electrical resistance value once became zero (0Ω) at a temperature near 40 K during the cooling process of the first cooling-warming process as the 25-th cycle of heat treatment, the electrical resistance value started to fall toward zero at a temperature near 50 K and became a zero resistance at a temperature near 60 K (superconducting transition) during the warming process of the first cooling-warming process as the 25-th cycle of heat treatment, and after that, the zero resistance state was maintained even when the temperature was raised up to a temperature of 300 K. Since the superconducting transition temperature of niobium used as the constituent is about 9.2 K, the zero resistance was obtained at a temperature greatly exceeding the superconducting transition temperature.

From the above, the second precursor having the electrical resistance characteristic exhibiting electrical resistance value of 0Ω in a temperature range exceeding the bifurcation temperature was obtained.

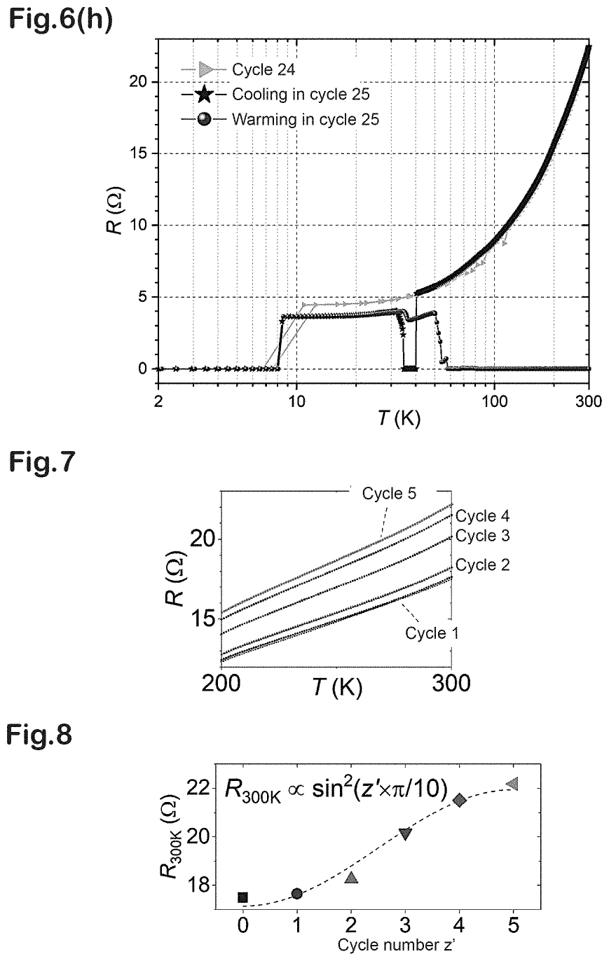

Next, in order to carry out the current application process on the second precursor, a direct current was applied between the terminals J₁ and J₅ in FIG. 4 under a temperature condition of 300 K while mounting the second precursor on the physical property measuring device, and voltage generated between the terminals J₂ and J₄ was measured to carry out the current application process. Note that the current application process was carried out by connecting a source/measure unit (B2911A made by Keysight Technologies Inc.) to the physical property measuring device. The results of the voltage-current characteristic measurement when the direct current was applied to the second precursor are illustrated in FIG. 10(a).

As illustrated in FIG. 10(a), when the direct current was increased from the initial value of 0 mA, a thermoelectromotive force once began to occur near 2 mA but settled into the zero resistance again near 10 mA, and finally at 18.8 mA, the voltage reached 1 V as a compliance value set in the source/measure unit. In other words, the critical current value at which the second precursor lost the electrical resistance characteristic (zero resistance) was 18.8 mA.

Note that this operation also serves as the application of a current having a magnitude of the critical current value or more to the second precursor in the same direction as the current application direction in the pretreatment process or a direction opposite thereto. In other words, the square wave current that reverses positive and negative is applied between the terminals J₁ and J₅ in FIG. 4 in the pretreatment process, and the direct current is applied between the terminals J₁ and J₅ in FIG. 4 in the current application process to maintain the properties of the first precursor obtained in the pretreatment process.

From the above, the third precursor that does not exhibit the electrical resistance characteristic (zero resistance) was obtained.

The results of the voltage-current characteristic measurement when the direct current was applied to the third precursor by subsequently using the source/measure unit are illustrated in FIG. 10(b).

As illustrated in FIG. 10(b), it can be confirmed that the properties as the superconductor disappear by the application of the current with the magnitude of the critical current value or more.

In other words, the resistance values exhibited 20Ω metallic properties during current values of 0 μA to +1 μA, but voltage-current characteristics exhibiting insulator properties to reach a resistance value of 2.2 kΩ when the current values were less than 0 μA and exceeded 1 μA were obtained, and no zero resistance could not be confirmed anywhere, resulting in the fact that the properties as the superconductor disappeared.

However, the voltage-current characteristics are not symmetric with respect to the origin, and this is unusual. The periodic structure body is an insulator for negative current, and is in a mixed state of the metal and the insulator for positive current in the same direction as the current with the magnitude of the critical current value or more applied in the current application process. This suggests that holes are injected into the periodic structure body by applying the current of the critical current value or more to the second precursor, and these holes behave metallically in a positive current region when the amount of current is small, and behave like an insulator as the amount of current increases.

Next, the second cooling-warming process was carried out on the third precursor to produce the phononic material according to Example 1.

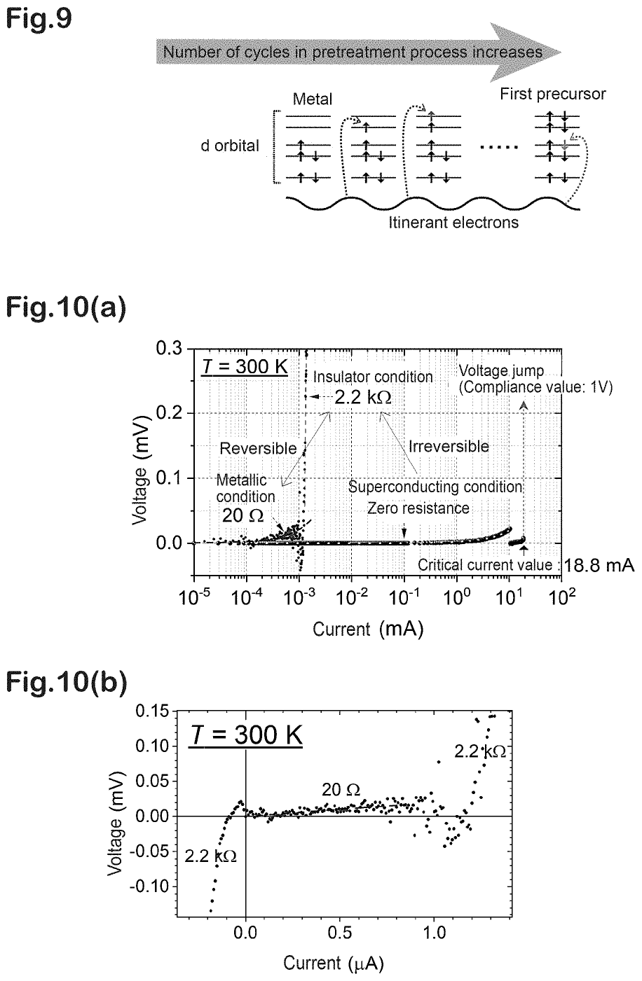

The method for carrying out the second cooling-warming process is the same as that for the first cooling-warming process. In other words, the second cooling-warming process was carried out while performing the electrical resistance measurement test by applying the square wave current that reverses positive and negative with the amplitude of ±10 μA, where the magnitude of the magnetic field inside the physical property measuring device was so set that a magnetic flux density penetrating the phononic material vertically was 10 μT or less under an atmosphere of helium gas of about 200 Pa, and the physical property measuring device was set to “AC DRIVE MODE” and “STANDARD CALIBRATION MODE” was selected. The status of carrying out the second cooling-warming process and the transition status of electrical resistance values are illustrated in FIG. 11(a) and FIG. 11(b). Note that FIG. 11(a) is a graph for describing the status of carrying out the second cooling-warming process on the phononic material according to Example 1 and the transition status of electrical resistance values, and FIG. 11(b) is a partially enlarged graph in which a range of 20 K to 60 K in FIG. 11(a) is enlarged.

As illustrated in FIG. 11(a) and FIG. 11(b), zero resistance (superconducting transition) was confirmed at a temperature near 51 K during a warming process of the second cycle, and after that, the zero resistance state was maintained even when the temperature raised up to a temperature of 300 K.

Therefore, the periodic structure body in the phononic material according to Example 1 recovers the characteristic (zero resistance) as the superconductor.

In addition to this, in the periodic structure body in the phononic material according to Example 1, it is considered that parts with the properties as the superconductor recovered and parts having properties as the semiconductor with excessive holes acquired in the current application process were formed periodically according to the periodic array of the structures, and hence that junctions of these parts are periodically formed in the periodic structure body to be verified below.

<Verification Based on Differential Conductance Voltage Characteristic>

First, in order to reveal the nature of the phononic material according to Example 1, a differential conductance voltage characteristic (dI/dV−V) of the phononic material according to Example 1 was measured. The measurement environment is a laboratory environment, that is, the temperature is room temperature, the magnetic field is geomagnetism, and the pressure is the atmospheric pressure.

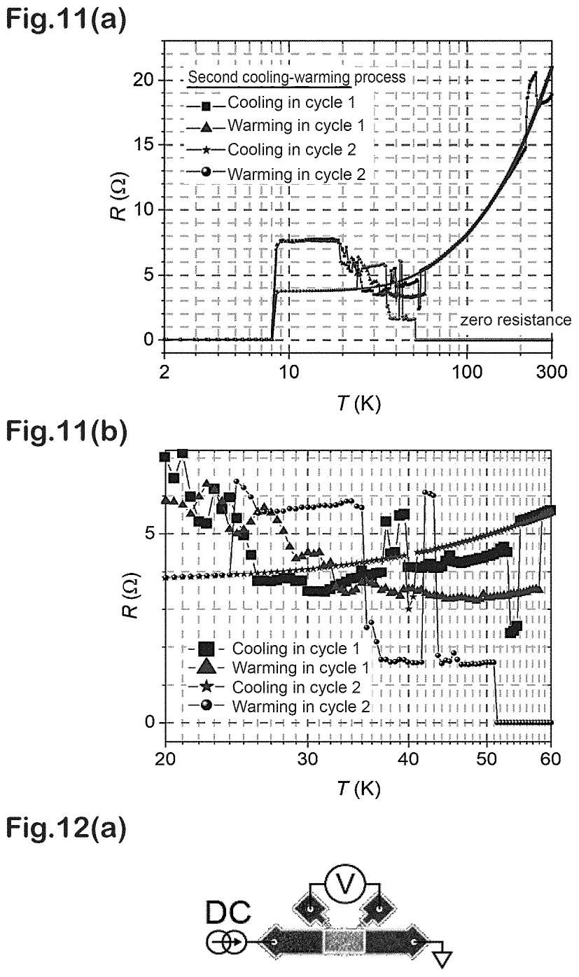

Specifically, the direct current was applied between the terminals J₁ and J₅ in FIG. 4 to measure voltage generated between the terminals J₂ and J₄, and the applied current was differentiated by the measured voltage to acquire a differential conductance value for each measured voltage. Then, the differential conductance was plotted on the vertical axis and the measured voltage was plotted on the horizontal axis to acquire differential conductance voltage characteristics. Note that the differential conductance voltage characteristics were measured by using the source/measure unit. An equivalent circuit of a measuring circuit used to measure the differential conductance voltage characteristics of the periodic structure body in the phononic material according to Example 1 is illustrated in FIG. 12(a). Further, the results of the differential conductance voltage characteristic measurement of the periodic structure body in the phononic material according to Example 1 are illustrated in FIG. 12(b). Further, about FIG. 12(b), the results of plotting the square of voltage on the horizontal axis are illustrated in FIG. 12(c).

As illustrated in FIG. 12(b), the differential conductance voltage characteristics of the phononic material according to Example 1 are obviously asymmetric with respect to the origin, and characteristic peaks are observed at voltages of −0.85 V, −0.05 V, +1.05 V, and +1.85 V.

Further, as illustrated in FIG. 12(c), it is found that the differential conductance is proportional to the square of voltage in voltage regions indicated at (I) and (III). A superconductor that meets such a relationship is known as a d-wave superconductor, which plays an important role in causing electrons in d orbital to acquire a property as the superconductor (see Reference Document 5 below).
Reference Document 5: K. Tanabe et al., Phys. Rev. B 53, 9348 (1996)

As stated that electrons are localized to occupy the d orbital completely while meeting the Friedel sum rule on the way that the periodic structure body acquires properties as the superconductor, the properties as the superconductor of the periodic structure body in the phononic material according to Example 1 are also brought by electrons in the d orbital, and it can be said that the results illustrated in FIG. 12(c) are natural consequences.

Further, voltage regions (I) to (III) illustrated in FIG. 12(b) correspond respectively to voltage regions (I) to (III) illustrated in FIG. 12(c). However, as illustrated in FIG. 12(c), the differential conductance voltage characteristic in voltage region (II) behaves differently from the differential conductance voltage characteristics in voltage regions (I) and (III).

Among these, since both the differential conductance voltage characteristics in voltage regions (I) and (III) are brought by the d-wave superconductor, and the voltage width of voltage regions (I) and (III) is both 0.8 V, it is found that the superconducting gap about a property (zero resistance) as the superconductor that the periodic structure body exhibits in the phononic material according to Example 1 is 0.8 eV.

Further, since the differential conductance voltage characteristic in voltage region (II) illustrated in FIG. 12(b) and FIG. 12(c) is brought by a semiconductor having excessive holes, and the voltage width of voltage region (II) is 1.1 V, it is found that the semiconductor band gap about a property as the semiconductor that the periodic structure body exhibits in the phononic material according to Example 1 is 1.1 eV.

Note that relationships among respective conditions, that is, the critical current value (18.8 mA), the superconducting gap (A=0.8 eV), the electrical resistance value (20Ω) of the metallic state at 300 K illustrated in FIG. 10(b), and the temperature (300 K) at which the critical current value was measured, satisfy the Ambegaokar-Baratoff relational expression.

<Verification Based on Capacitance-Voltage Characteristic>

Further, in order to reveal the nature of the phononic material according to Example 1, a capacitance-voltage characteristic (C-V) of the phononic material according to Example 1 was measured. The measurement environment is the laboratory environment, that is, the temperature is room temperature, the magnetic field is geomagnetism, and the pressure is the atmospheric pressure.

Specifically, the measurement was performed as follows.

The amount of current when an AC voltage with a magnitude of 50 mV and a frequency of 10 kHz was applied between the terminals J₁ and J₅ was read with respect to each direct current applied between the terminals J₂ and J₄ in FIG. 4, and time integration of the amount of current was performed to calculate the amount of charge accumulated in the periodic structure body in the phononic material according to Example 1. From the direct voltage value and the charge amount value, the capacitance of the periodic structure body in the phononic material according to Example 1 was determined to acquire capacitance-voltage characteristics by plotting the capacitance on the vertical axis and the direct voltage on the horizontal axis. Note that capacitance-voltage characteristics were measured by using a semiconductor device parameter analyzer (B1500A made by Keysight Technologies Inc.).

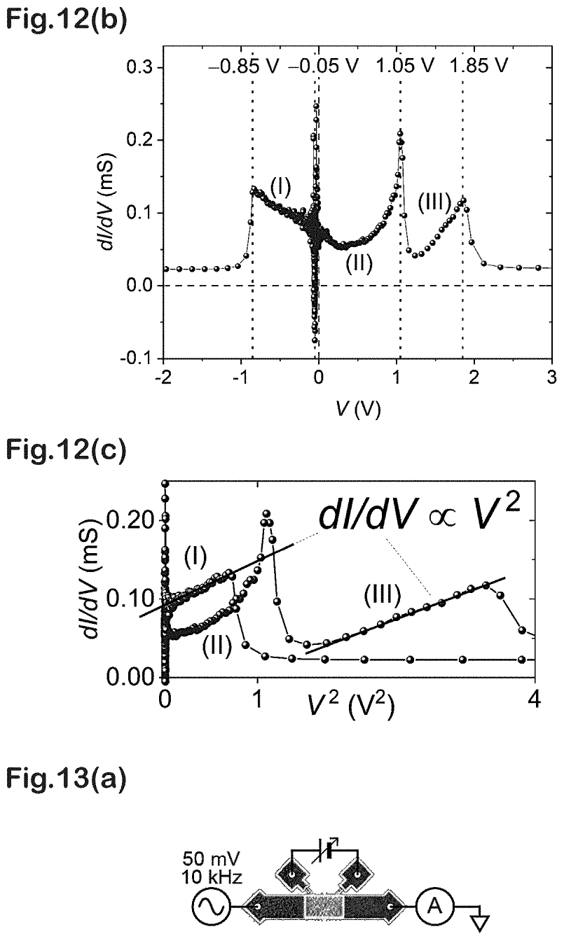

An equivalent circuit of a measuring circuit used to measure the capacitance-voltage characteristics of the periodic structure body in the phononic material according to Example 1 is illustrated in FIG. 13(a). Further, the results of the capacitance-voltage characteristic measurement of the periodic structure body in the phononic material according to Example 1 are illustrated in FIG. 13(b).

As illustrated in FIG. 13(b), the capacitance decreases as the voltage increases in a direction from negative to positive, but the capacitance is inverted at V=−0.05 V to increase. Such an inversion behavior is generally observed in a junction with a p-type semiconductor on one side (for example, MOS diode).

In other words, it is suggested that there is a material order similar to that of the p-type semiconductor in the periodic structure body in the phononic material according to Example 1, and a junction interface is formed by the p-type semiconductor and the d-wave superconductor. Further, it is found that the periodic structure body in the phononic material according to Example 1 forms the depletion layer in a voltage region of V<−0.05 V, and forms an inversion layer in a voltage region of −0.05 V<V<+1.05 V.

In the following, such a structural characteristic that the periodic structure body in the phononic material according to Example 1 behaves to make a junction between the p-type semiconductor and the d-wave superconductor is simply called a “junction structure according to Example 1.”

In the capacitance-voltage characteristic illustrated in FIG. 13(b), V=−0.05 V is set to a boundary value between the depletion layer and the inversion layer, and V=+1.05 V is set to a boundary value of the inversion behavior. A point to pay attention to is that these boundary values match voltage values indicative of characteristic peaks observed from FIG. 12(b) as the results of the differential conductance voltage characteristic measurement, which is important in considering a band structure of the junction structure in Example 1 to be described next.

Further, a graph in which FIG. 13(b) is plotted as the reciprocal of the square of capacitance on the vertical axis (Mott-Schottky plot, 1/C²−V) is illustrated in FIG. 13(c).

A linear part of the graph can be extrapolated to determine a flat band potential V_{FB} of the junction structure in Example 1 from voltage values intersecting the axis of 1/C²=0F⁻², which is V_{FB}=−3.1 V.

In general, when a voltage corresponding to the flat band potential V_{FB} is applied to both ends of a junction, an energy band formed near the junction interface of the junction structure becomes such a state that there is no bending of the band. Conversely, in a case where a junction structure having a large flat band potential V_{FB}, when the voltage applied to both ends of the junction structure is 0 V, it means that the energy band is bent a lot near the junction interface.

Here, the large and small distinction in the magnitude of the flat band potential V_{FB} is determined by comparing it with the size of a band gap with the semiconductor or the like that constructs part of the junction.

As described above, in the junction structure in Example 1, the sizes of the semiconductor band gap and the superconducting gap are 1.1 eV and 0.8 eV, respectively, and both are smaller than the magnitude of the flat band potential V_{FB}.

Therefore, the flat band potential V_{FB} of the junction structure in Example 1 is determined to be “large.” In other words, when the voltage applied to both ends of the junction structure in Example 1 is 0 V, the energy band formed near the junction interface is bent a lot.

<Consideration of Band Structure>

Based on the results of the differential conductance voltage characteristic measurement and the results of the capacitance-voltage characteristic measurement described above, the band structure of the junction structure in Example 1 is considered.

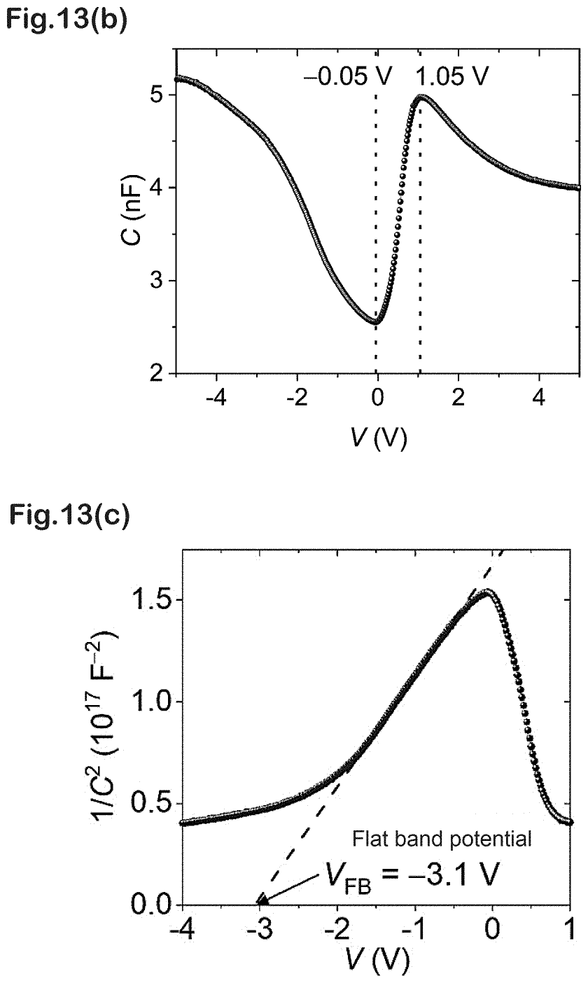

The status of the band structure at the junction interface of the junction structure in Example 1 and the status of carrier transport are illustrated in FIG. 14(a) and FIG. 14(b). Note that FIG. 14(a) is a schematic diagram illustrating a band structure when a voltage of 0 V is applied to both ends of the junction structure in Example 1, and FIG. 14(b) is a schematic diagram illustrating a band structure when the voltage applied to both ends of the junction structure in Example 1 is in five voltage regions with voltage values (V=−0.85 V, −0.05 V, +1.05 V, and +1.85 V) as boundary values at four characteristic peaks illustrated in FIG. 12(b).

In FIG. 14(a) and FIG. 14(b), a band structure of the p-type semiconductor when the semiconductor band gap is 1.1 eV is illustrated on the left side and a band structure of the superconductor when the superconducting gap is 0.8 eV is illustrated on the right side in respective band structures. Further, the Fermi levels of the p-type semiconductor and the superconductor are indicated by the dotted lines, and the Fermi levels of the p-type semiconductor and the superconductor match each other when the voltage applied to both ends of the junction structure in Example 1 is 0

V.

Further, it is assumed that the Fermi level of the p-type semiconductor is higher by 0.05 eV than the edge level of the valence band of the p-type semiconductor.

Further, an energy band formed at the junction interface of the junction structure in Example 1 is bent a lot due to a large flat band potential V_{FB}, and the Cooper pair on the superconductor side (indicated by a pair of black circles in the figures) is trapped in a deep energy potential well.

Further, in the figures, black dots represent electrons and while circles represent holes, and the states of transporting them are indicated by solid arrows in the horizontal direction, respectively.

Further, holes are abundantly present near the Fermi level of the p-type semiconductor, and holes are diffused to the superconducting side at the junction interface. In other words, a built-in electric field E_{D} is formed at the junction interface. The polarity of the built-in electric field E_{D} is indicated by the broken arrow at the bottom of each figure. The direction of the broken arrow is a direction in which the built-in electric field E_{D} goes from the positive polarity to the negative polarity. Further, the thickness of the broken arrow represents the magnitude of the built-in electric field E_{D}.

When the voltage applied to both ends of the junction structure in Example 1 is 0 V (FIG. 14(a)), abundant electrons existing in the valence band on the p-type semiconductor side make acceleration motion toward the superconductor side by the built-in electric field E_{D} (with a positive polarity on the superconductor side). At the time, the Andreev reflection occurs.

In other words, the electrons cannot occupy the energy level on the superconductor side because there is no energy level as a destination of the electrons making acceleration motion due to the superconducting gap. Instead, the electrons are reflected as holes from the superconductor side to the p-type semiconductor side. At the time, electrons and holes with charged polarities opposite to each other go in opposite directions, respectively, that is, current spontaneously flows through the junction interface even when the voltage applied to both ends of the junction structure in Example 1 is 0 V.

A state of increasing the voltage (bias voltage) applied to both ends of the junction structure in Example 1 in a direction from negative to positive will be described while referring to FIG. 14(b).

First, in voltage region (i) of V<−0.85 V as the first one from the left, the edge level of the valence band on the p-type semiconductor side is higher than a conduction band edge level on the superconductor side, and abundant electrons existing in the valence band on the p-type semiconductor side quantum-mechanically tunnel into the superconductor side. Further, the behavior of carrier transport at this time follows Ohm's law.

This is consistent with the result that the differential conductance value confirmed in the voltage region of V<−0.85 V of the differential conductance voltage characteristic (FIG. 12(b)) is constant, that is, that the differential conductance follows Ohm's law.

Next, when the bias voltage is increased toward (ii) V=−0.05 V as the second one from the left, the energy level of the p-type semiconductor goes down as a whole. When the edge level of the valence band of the p-type semiconductor goes down to an energy level with the existence of the superconductor gap, that is, in the voltage region of V>−0.85 V, the Andreev reflection occurs, and electrons are caused by the bias voltage to make acceleration motion from the valence band of the p-type semiconductor toward a gap region of the superconductor but the electrons cannot occupy the energy level on the superconductor side. Instead, holes are transported from the superconductor side to the semiconductor side. The effect of the Andreev reflection becomes the strongest when the edge level of the valence band of the p-type semiconductor in which abundant electrons exist matches the Fermi level of the superconductor, that is, at V=−0.05 V.

This is consistent with both the result that the differential conductance exhibits a behavior proportional to the square of voltage in the voltage region of −0.85 V<V<−0.05 V in the differential conductance voltage characteristic (FIG. 12(b)), that is, that carrier transport involving superconductivity was performed in this voltage region, and the result that differential conductance values form a peak at V=−0.05 V, that is, that carrier transport involving superconductivity was most strongly observed.

Further, since the Andreev reflection that occurs when the bias voltage is V=−0.05 V most reduces the number of holes on the superconductor side of the depletion layer and most reduces the number of electrons on the semiconductor side of the depletion layer, the built-in electric field E_{D} is most weakened at V=−0.05 V.

This is consistent with the result that the capacitance-voltage characteristic (FIG. 13(b)) exhibited the minimum value at V=−0.05 V.

Next, when the bias voltage is raised toward (iii) −0.05 V<V<+1.05 V as the third one from the left, and the Fermi level of the p-type semiconductor becomes lower than the Fermi level of the superconductor, the number of electrons on the semiconductor side of the depletion layer begins to increase.

Such a behavior is confirmed even in general junction structures, and the depletion layer turns to an inversion layer at this time. In other words, the increase in the number of electrons on the semiconductor side of the depletion layer means that the built-in electric field E_{D} is strengthened.

This is consistent with the behavior of increasing capacitance in the voltage region of V>−0.05 V in the capacitance-voltage characteristic (FIG. 13(b)).

Although the Andreev reflection occurs even in the voltage region of −0.05 V<V<+1.05 V, the horizontal solid arrow that indicates the state of carrier transport is omitted in a band structure (iii) as the third one from the left to avoid complicated depiction.

Next, when the bias voltage is raised toward (iv) V=+1.05 V as the fourth one from the left, and the conduction band edge level of the p-type semiconductor matches the Fermi level of the superconductor (V=+1.05 V), the Andreev reflection becomes the strongest again.

This is consistent with the result that the differential conductance values form a peak at V=+1.05 V in the differential conductance voltage characteristic (FIG. 12(b)).

Further, at this time, such a carrier distribution that the number of holes on the superconductor side of the inversion layer becomes the largest and the number of electrons on the semiconductor side of the inversion layer becomes the largest is formed, and the built-in electric field E_{D} becomes the strongest at V=+1.05 V.

This is consistent with the result that the capacitance-voltage characteristic (FIG. 13(b)) exhibited the maximum value at V=+1.05 V.

Next, the Andreev reflection continues in the process of raising the bias voltage toward (v) of V>+1.85 V as the fifth one from the left. The Andreev reflection continues until the edge level of the conduction band of the p-type semiconductor matches the edge level of the valence band of the superconductor, that is, until the bias voltage reaches V=+1.85 V.

This is consistent with the result that the differential conductance exhibits the behavior proportional to the square of voltage in the voltage region of +1.05 V<V<+1.85 V in the differential conductance voltage characteristic (FIG. 12(b)), that is, that carrier transport involving superconductivity was performed in this voltage region.

Further, in voltage region (v) of V>+1.85 V as the fifth one from the left, the edge level of the conduction band of the p-type semiconductor becomes lower than the edge level of the valence band of the superconductor, and holes quantum-mechanically tunnel from the conduction band of the p-type semiconductor into the superconductor side. The behavior of carrier transport at this time follows Ohm's law.

This is consistent with the result that the differential conductance value confirmed in the voltage region of V>+1.85 V in the differential conductance voltage characteristic (FIG. 12(b)) is constant, that is, that the differential conductance follows Ohm's law.

Although the capacitance-voltage characteristic (FIG. 13(b)) exhibit a tendency to decrease with increase in bias voltage after exhibiting the maximum value of V=+1.05 V, the polarity of the bias voltage in the voltage region is opposite to the polarity of the built-in electric field E_{D} in this tendency, and this is caused by the fact that the built-in electric field E_{D} is weakened as the bias voltage is raised. Such a behavior is also confirmed in general junction structures (for example, MOS diode).

Based on the above considerations, a verification test of whether or not current spontaneously flows into the junction structure in Example 1 in such a situation that the potential gradient is not given was performed. The measurement environment is the laboratory environment, that is, the temperature is room temperature, the magnetic field is geomagnetism, and the pressure is the atmospheric pressure.

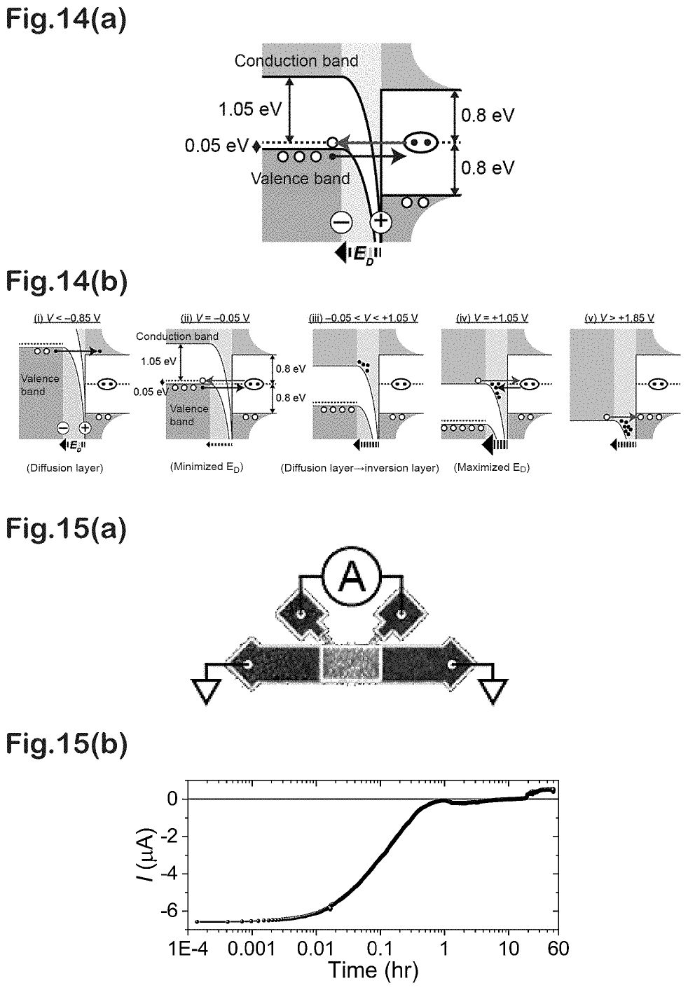

Specifically, changes over time in current flowing between the terminals J₂ and J₄ in such a situation that direct voltage of 0V was applied between the terminals J₁ and J₅ in FIG. 4, that is, no potential difference between the terminals J₁ and J₅ was given, were measured. Note that the measurement of current changes over time was made by using the source/measure unit. An equivalent circuit of a measuring circuit used to measure the changes over time in current flowing through the junction structure in Example 1 is illustrated in FIG. 15(a).

Further, the measurement results of the changes over time in current flowing through the junction structure in Example 1 are illustrated in FIG. 15(b).

As illustrated in FIG. 15(b), it can be confirmed that current with an amplitude of a few μA flows through the junction structure in Example 1, that is, through the periodic structure body in the phononic material according to Example 1 even in the situation that the potential gradient is not given.

With the passage of measurement time, the current increases in the positive direction for a while, and the amount of current exhibits a behavior approaching 0 μA about one hour after the start of the measurement. However, the current changes the polarity and begins to flow 12 hours after the start of the measurement. In other words, the current begins to flow in the opposite direction about 12 hours after the start of the measurement. The amount and polarity of current flowing through the junction structure in Example 1 are determined by the built-in electric field E_{D} at the junction interface of the junction structure in Example 1 and the Andreev reflection.

In other words, it is inferred that the built-in electric field and the Andreev reflection, which are causes of each other and results of each other, determine the amount and polarity of current flowing through the junction interface while harmonizing strength and frequency, respectively.

Note that the source/measure unit used for the measurement does not affect anything about the current with the amplitude of a few μA confirmed in the measurement because the accuracy is better than 4 nA and the measurement resolution is better than 10 μA in a current range set in the measurement.

From the perspective of applying the present invention to industrial products, it is important to check whether or not the current spontaneously flowing through the junction structure in Example 1 can flow into an external electrical circuit (load) externally connected. Therefore, a measurement to confirm whether or not the junction structure in Example 1 can apply current to the external electrical circuit (load) was performed by connecting a metal film resistor of 1 MΩ in series with the junction structure (the periodic structure body) in Example 1 to read voltage generated between both ends of the resistor. The measurement corresponds to a discharge test in the battery field. The measurement environment is the laboratory environment, that is, the temperature is room temperature, the magnetic field is geomagnetism, and the pressure is the atmospheric pressure. Further, the measurement was performed by mounting the phononic material according to Example 1 in a diecast box and covering it with a diecast cover. Thus, the phononic material according to Example 1 was placed in a dark place and the discharge test was carried out to check if it has applications to industrial products different from solar cells composed of the pn junctions.

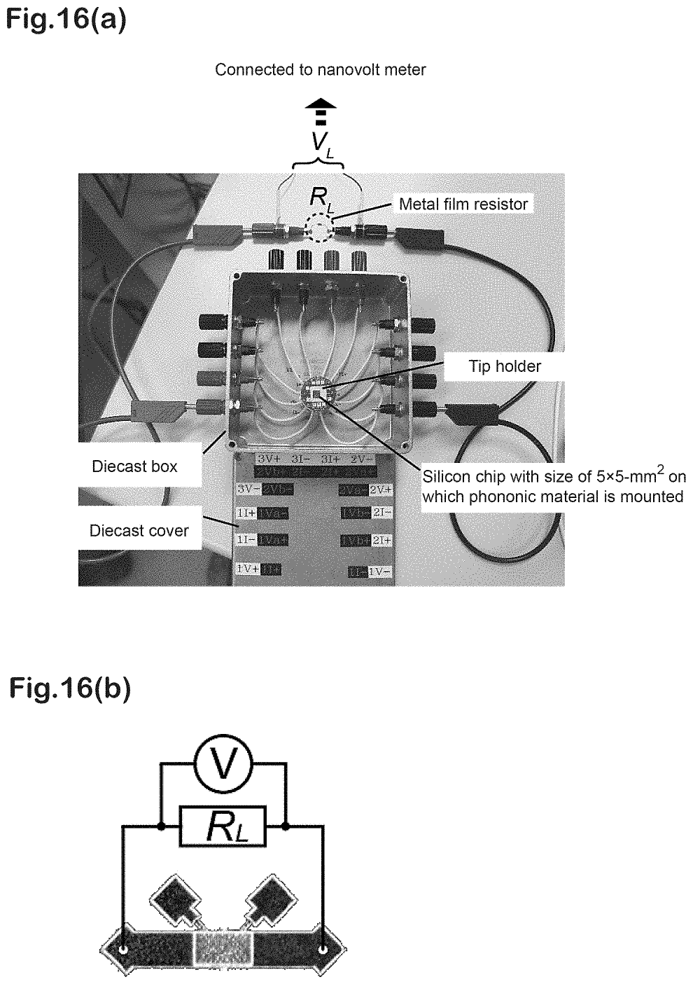

Specifically, a photo of an experimental setup of the measurement is illustrated in FIG. 16(a). The metal film resistor (YR1B1M0CC made by TE Connectivity, Inc.) with R_{L}=1MΩ was connected in series with the junction structure (the periodic structure body) in Example 1, and voltage VL generated between both ends of the resistor was read by a nanovolt meter (2182A made by Keithley Instruments, Inc.) to measure changes over time in voltage VL. More specifically, the metal film resistor with R_{L}=1MΩ was connected between the terminals J₁ and J₅ in FIG. 4. An equivalent circuit of an electrical circuit for confirmation measurement, which is connected to an external electrical circuit, is illustrated in FIG. 16(b). Further, the measurement results of changes over time in voltage VL generated between both ends of the metal film resistor connected to the outside of the phononic material according to Example 1 are illustrated in FIG. 16(c).

As illustrated in FIG. 16(c), VL exhibits significant values, and the phononic material according to Example 1 applies current to the metal film resistor connected to the periodic structure body. The median of VL during a measurement period of about 50 days is about 0.4 mV, and the median of current supplied by the phononic material according to Example 1 to the metal film resistor with R_{L}=1MΩ during the measurement period is about 0.4 nA.

From the fact that the amount of current spontaneously flowing through the junction structure (the periodic structure body) in Example 1 was a few μA (see FIG. 15(b)), this result indicates that only a small part of the current flowing through the junction structure in Example 1 flows into the external electrical circuit (load).

This cause is not only a natural reason that the external electrical circuit is the load but also because there is a need for current flowing through the junction structure (the periodic structure body) in Example 1 to overcome energy barriers formed between the periodic structure body and parts without the periodic structure body and parts (i.e., normal metal parts) without the periodic structure body indicated by the terminals J₁ and J₅ in FIG. 4 in order to flow out to the outside.

Further, as illustrated in FIG. 16(c), the VL value keeps decreasing immediately after the start of measurement. On the other hand, the VL value suddenly becomes smaller toward 0 mV after about 25 days have passed, and such a behavior that the value is recovered again and then decreased toward 0 mV again is repeated.

VL²/R_{L} gives power to be consumed by the metal film resistor at each measurement time, and time integration of VL²/R_{L} can be performed from immediately after the start of measurement to an arbitrary measurement time to get the sum of energy consumed by the metal film resistor during a period until the arbitrary measurement time, and this sum can be divided by the measurement time to know the time average of energy consumed by the metal film resistor. Here, the value of R_{L}=1MΩ as the load of this measurement is sufficiently larger than the resistance value of lead wires, etc. Therefore, the time average of energy consumed by the metal film resistor means the time average of energy produced by the phononic material according to Example 1. Changes over time in time average of energy produced by the phononic material according to Example 1 are illustrated in FIG. 16(d).

In FIG. 16(c), after about 25 days have passed, the VL value repeated decrease and recovery, but it is moving in a direction of decreasing energy as a whole as illustrated in FIG. 16(d), which is not against the law of conservation of energy.

Note that the nanovolt meter used for the measurement has a measurement resolution better than 10 nV in a voltage range set for the measurement, and does not affect the voltage with a magnitude of sub mV confirmed in the measurement at all.

Even when a potential gradient is given to the junction structure (the periodic structure body) in Example 1 (other than 0 V), current flows and the current is supplied to the external electrical circuit. However, in either case, the current at the time exhibits a constant value for any potential gradient. In other words, the present invention can establish a current standard, and it is important for application to industrial products.

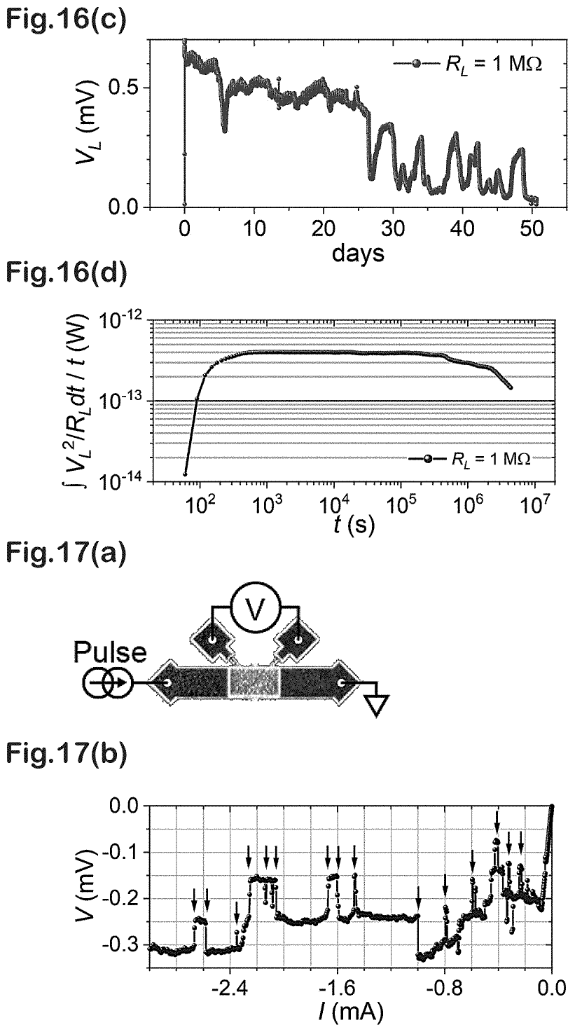

Specifically, the phononic material according to Example 1 was mounted on the physical property measuring device, the magnitude of the magnetic field inside the physical property measuring device was so set that the magnetic flux density penetrating the phononic material vertically was 10 μT or less, and a pulse current was applied between the terminals J₁ and J₅ in FIG. 4 at a temperature of 300 K under an atmosphere of helium gas of about 200 Pa to measure voltage generated between the terminals J₂ and J₄ in order to measure voltage-pulse current characteristics. An equivalent circuit of a measuring circuit used to measure the voltage-pulse current characteristics is illustrated in FIG. 17(a).

The reason for using the pulse current in this measurement is to capture a relatively fast phenomenon occurring in the junction structure (the periodic structure body) in Example 1. From the results of the capacitance-voltage characteristic measurement (FIG. 13(b)), the capacitance of the junction structure (the periodic structure body) in Example 1 is 2.6 nF, which is large even near the voltage of 0 V. Therefore, from an impedance point of view, the relatively fast phenomenon occurring in the junction structure (the periodic structure body) in Example 1 cannot be captured unless the pulse current has a rise time and a fall time of a few ns. When the direct current, rather than the pulse current, is applied between the terminals J₁ and J₅ in FIG. 4, the results of the differential conductance voltage characteristic measurement are obtained (FIG. 12(b)).

The voltage-pulse current characteristic measurement was performed by setting the physical property measuring device to “DC DRIVE MODE.” Specifically, the current applied to the junction structure (the periodic structure body) in Example 1 is a square wave current that does not reverse positive and negative, that is, a one-sided polarity pulse current. The pulse current was applied ten times to the junction structure (the periodic structure body) in Example 1 in a cycle of 8.33 Hz for each amplitude representing a value of current applied, and the mean of the voltage values measured in the last two times was read to perform the voltage-pulse current characteristic measurement. The results of the voltage-pulse current characteristic measurement are illustrated in FIG. 17(b).

As indicated by the arrows in FIG. 17(b), such a phenomenon that voltage suddenly changes to a different value at a certain current value can be confirmed more than once. Conversely, it means that the junction structure (the periodic structure body) in Example 1 can flow current having a constant value instantaneously out of the junction structure (the periodic structure body) in Example 1.

As described above, this measurement result was obtained by applying the pulse current between the terminals J₁ and J₅ in FIG. 4 to measure voltage generated between the terminals J₂ and J₄, but this is virtually equivalent to the application of voltage between the terminals J₂ and J₄ in FIG. 4 to measure current flowing between the terminals J₁ and J₅.

However, in the case of the latter measurement method, a measurement circuit to read instantaneously flowing current is required separately, and hence the measurement becomes complicated.

In either case, the application of voltage between the terminals J₂ and J₄ in FIG. 4 means to give a potential gradient to the junction structure (the periodic structure body) in Example 1, and the fact that the current flowing between the terminals J₁ and J₅ at the time exhibits a constant value means that the phononic material can flow out the current having the constant value to an external electrical circuit by the potential gradient given to the periodic structure body.

### DESCRIPTION OF REFERENCE NUMERALS

1, 20 phononic material
2, 22a, 22b constituent
2′, 12, 22, 22′ periodic structure body
3, 13, 23a, 23b, 23′ structure
4, 24 substrate
5, 25 spacer
26 cubic block area
32 niobium layer
33 through hole
36 rectangular block region

1. A phononic material comprising
a periodic structure body in which structures are periodically and regularly disposed in a constituent containing elements having d orbital,
wherein the periodic structure body exhibits a voltage-current characteristic to make current flow when a potential gradient is 0 V.

2. The phononic material according to claim 1, wherein the periodic structure body can supply current to an external electrical circuit when the potential gradient is 0 V.

3. The phononic material according to claim 1, wherein the periodic structure body exhibits a voltage-current characteristic to make current flow when a potential gradient is given.

4. The phononic material according to claim 1, wherein the periodic structure body can supply current to an external electrical circuit when a potential gradient is given.

5. The phononic material according to claim 1, wherein the constituent contains a transition metal element.

6. The phononic material according to claim 1, wherein the periodic structure body is formed in a layer, and the structures are through holes.

7. The phononic material according to claim 6, wherein an opening diameter of each through hole is 1 nm to 10 mm.

8. The phononic material according to claim 6, wherein an interval between adjacent two through holes is 1 nm to 0.1 mm.

9. The phononic material according to claim 6, wherein a thickness of the periodic structure body formed in the layer is 0.1 nm to 0.01 mm.

10. A method for producing the phononic material according to claim 1, comprising:
a pretreatment process to obtain a first precursor as the periodic structure body that does not develop a bifurcation phenomenon by carrying out a heat treatment to warm the periodic structure body up to a temperature exceeding a bifurcation temperature after cooling the periodic structure body up to a temperature lower than the bifurcation temperature in a state of applying a unidirectional current to the periodic structure body until the bifurcation phenomenon disappears, where the bifurcation phenomenon is a phenomenon in which, when a cooling resistance temperature characteristic of the periodic structure body in a cooling process of continuous heat cycles to raise temperature after cooling the periodic structure body is compared with a warming resistance temperature characteristic of the periodic structure body in a warming process, the warming resistance temperature characteristic bifurcates from the cooling resistance temperature characteristic to exhibit a high electrical resistance value at a common temperature, and the bifurcation temperature is a temperature at which the cooling resistance temperature characteristic and the warming resistance temperature characteristic bifurcate each other in the bifurcation phenomenon;
a first cooling-warming process to obtain a second precursor as the periodic structure body having an electrical resistance characteristic exhibiting an electrical resistance value of 0Ω or less in a temperature range exceeding the bifurcation temperature by carrying out a heat treatment to warm the first precursor up to a temperature exceeding the bifurcation temperature after cooling the first precursor up to a temperature lower than the bifurcation temperature until the warmed first precursor exhibits the electrical resistance value of 0Ω or less;
a current application process to obtain a third precursor as the periodic structure body that does not exhibit the electrical resistance characteristic by applying current with a magnitude of a critical current value or more to the second precursor in the same direction as the unidirectional current or a direction opposite thereto to lose the electrical resistance characteristic; and
a second cooling-warming process to carry out a heat treatment to warm the third precursor up to a temperature exceeding the bifurcation temperature after cooling the third precursor up to a temperature lower than the bifurcation temperature until the third precursor exhibits a voltage-current characteristic to make current flow when a potential gradient is 0 V.
